(19) United States
(12) Patent Application Publication
(10) Pub. No.: US 2025/0098520 A1
(43) Pub. Date: Mar. 20, 2025

(54) PHOTO-RECHARGEABLE BATTERY FOR GREATER CONVENIENCE, LOWER COST, AND HIGHER RELIABILITY SOLAR ENERGY UTILIZATION

(71) Applicants: Quinn Qiao, Jamesville, NY (US); Sally Mabrouk, Syracuse, NY (US); Ashim Gurung, Brookings, SD (US)

(72) Inventors: Quinn Qiao, Jamesville, NY (US); Sally Mabrouk, Syracuse, NY (US); Ashim Gurung, Brookings, SD (US)

(73) Assignee: Syracuse University, Syracuse, NY (US)

(21) Appl. No.: 18/728,157

(22) PCT Filed: Jan. 11, 2023
(86) PCT No.: PCT/US2023/010570

§ 371 Date: Jul. 11, 2024

(51) Int. Cl. H10K 85/50; H10K 30/20; H10K 30/57; H10K 85/20

(52) U.S. Cl. CPC H10K 85/50; H10K 30/211; H10K 30/57; H10K 85/215

(57) ABSTRACT

A single solar battery device formed by a solid-state Li battery intrinsically stacked on a monolithic triple junction solar cell sharing the same electrode in between. The solar cell generates a voltage high enough to directly photo-charge a Li battery at the required C-rate without use of a converter. The subcells of the monolithic triple junction solar cell are connected monolithically in series via optimized tunnel recombination junctions through which electrons and holes from the connected subcells can recombine. The intrinsic integration of the battery with solar cell enables using of a single device without an external cable connection, thus facilitating and decreasing the installation cost.

### CROSS-REFERENCE TO RELATED APPLICATIONS

The present application claims priority to US Provisional No. 63/298,330 filed on Jan. 11, 2022.

### STATEMENT REGARDING FEDERALLY SPONSORED RESEARCH AND DEVELOPMENT

This invention was made with government support under Grant No. NNX15AM83A awarded by the National Aeronautics and Space Administration Grant No. 1428992 awarded by the National Science Foundation. The government has certain rights in this invention.

### BACKGROUND OF THE INVENTION

### 1. FIELD OF THE INVENTION

The present invention relates to solar rechargeable batteries and, more specifically, to a solar battery device consisting of a solid-state Li battery intrinsically stacked on a monolithic triple junction solar cell.

### 2. DESCRIPTION OF THE RELATED ART

There is growing worldwide demand for renewable energy sources such as solar. However, one of the major challenges of photovoltaics is the intermittent irradiation resulting in fluctuating voltage, current and frequency. This reduces the power quality and reliability of solar energy, which could be solved by integrating PV systems with batteries that can back up solar energy for the period when sunlight is not stable or unavailable at night or due to weather such as clouds, rain, and snow.

There are different methods for storing PV energy. Electrochemical storage such as Li-ion batteries (LIB) are one of the preferred technologies due to their high-power, high-energy density, and high cell voltage. Most Li-ion batteries available in the market use liquid electrolyte causing technical and safety issues such as corrosion, leakage, flammability, and explosion. In addition, existing photovoltaics separately connected to battery systems use mechanically integrated solar panels and battery packs via wiring, cables, and converters. This results in large energy loss, complicated and expensive installation costs. Previous attempts to mechanically integrate solar cells (PSC) to a photo-charge lithium-ion battery showed low specific capacity due to significant energy loss.

Accordingly, there is a need in the art for a design that intrinsically integrates solar cells with batteries to enable the highest possible efficiency and convenience with significant lower costs.

### BRIEF SUMMARY OF THE INVENTION

The present invention comprises a solid-state Li battery integrated intrinsically with a monolithic triple junction solar cell having voltage and current high enough to directly photo-charge the battery at any required C-rate without a DC-DC converter. The solar battery targets over 30% photovoltaic able to photo-charge a Li battery at 0.5 C-1 C, 1000 cycles at 80% capacity retention, and 25° C. for 300 mAhg⁻¹ specific capacity and with a 150 Ah/m² areal capacity density.

More specifically, an embodiment of the present invention comprises a solar battery formed by a solar cell including rear subcell formed from crystalline silicon, a middle subcell formed from a medium bandgap perovskite positioned on the first subcell, and a front subcell formed from a wide bandgap perovskite positioned on the second subcell, wherein herein the rear subcell, the middle subcell, and the front subcell are connected monolithically in series so that current will flow in a single direction to provide a voltage output, and a solid state lithium battery coupled to the voltage output of the solar cell. The crystalline silicon of the rear subcell may be textured on a top surface and a bottom surface. The middle subcell may be formed from CH₃NH₃PbI₃ perovskite. The front subcell may be formed from FA_{0.8}MA_{0.1} Cs_{0.1}Pb (I_{0.7}Br_{0.2} Cl_{0.1})₃ perovskite. The rear subcell and the middle subcell may be interconnected by a layer of sputtered transparent indium tin oxide. The rear subcell and the middle subcell may be interconnected by a layer of n-doped hydrogenated amorphous silicon. The rear subcell and the middle subcell may be interconnected by a layer of hydrogenated intrinsic amorphous silicon. The middle subcell and the front subcell may be interconnected by a layer of ethoxylated poly-ethylenimine, aluminum-doped zinc oxide, and indium tin oxide. The middle subcell and the front subcell may be interconnected by a layer of [6,6]-phenyl C60 butyric acid methyl ester positioned between the layer of ethoxylated poly-ethylenimine, aluminum-doped zinc oxide, and indium tin oxide and the middle subcell. The solar battery may further comprise a layer of transparent rhodamine interconnected to the front subcell. A layer of [6,6]-phenyl C60 butyric acid methyl ester may be positioned between the front subcell and the layer of transparent rhodamine. A layer of silver may be positioned on the layer of transparent rhodamine to form a top electrode. The solid state lithium battery may be formed from a lithium iron phosphate cathode, a solid polymer and garnet electrolyte, and a lithium titanate anode. The solid state lithium battery may be formed from a lithium cobalt oxide cathode, a solid polymer and garnet electrolyte, and a lithium titanate anode. The solar cell and the solid state lithium battery may share an electrode positioned between the solar cell and the solid state lithium battery. BRIEF DESCRIPTION OF THE SEVERAL VIEWS OF THE DRAWING(S)

The present invention will be more fully understood and appreciated by reading the following Detailed Description in conjunction with the accompanying drawings, in which:

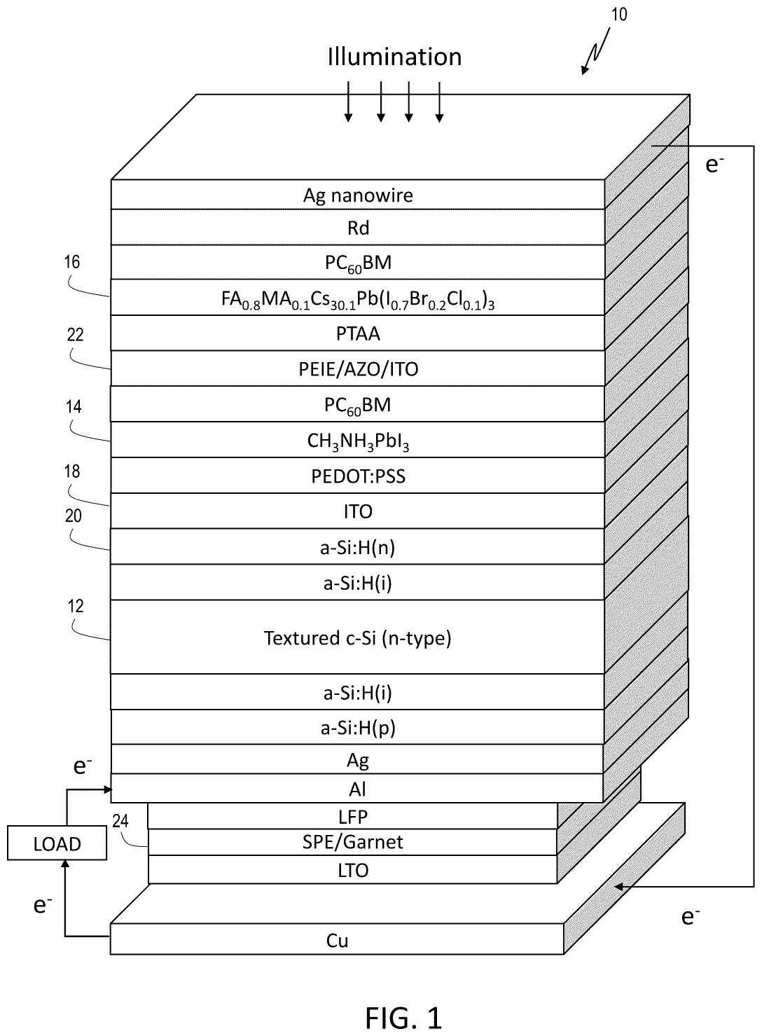

FIG. 1 is a schematic of a triple junction solar cell integrated solid Li-ion battery.

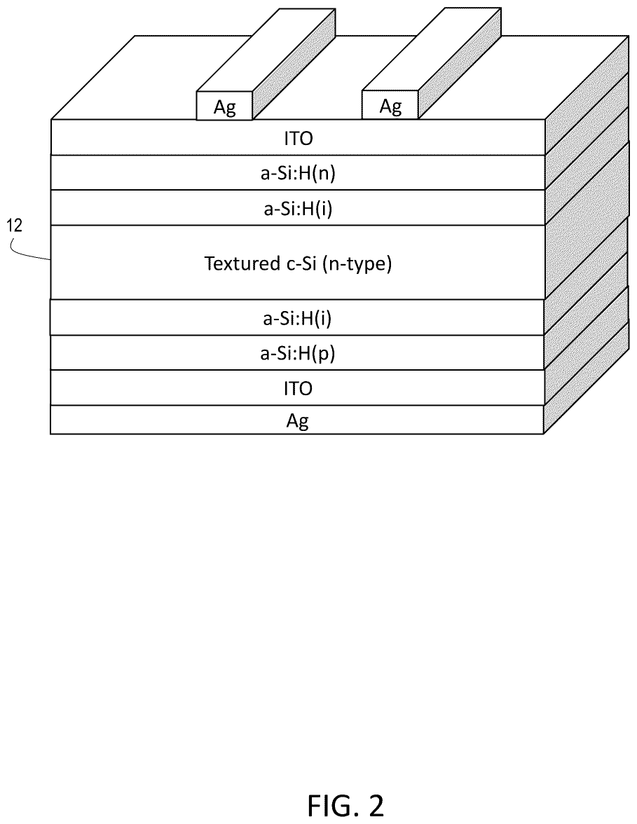

FIG. 2 is a schematic of the structure of a hetero-junction c-Si (1.1 eV) rear cell.

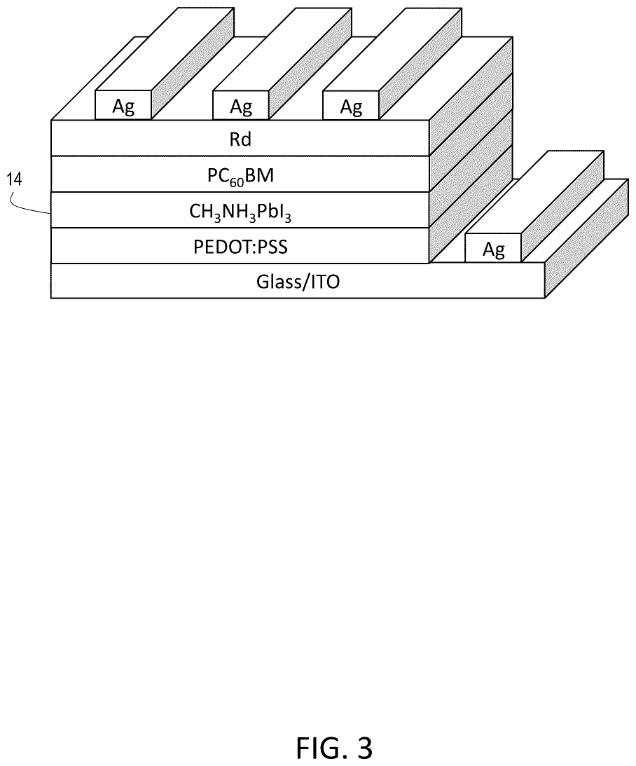

FIG. 3 is a schematic of the structure of a CH₃NH₃PbI₃ (1.55 eV) middle cell.

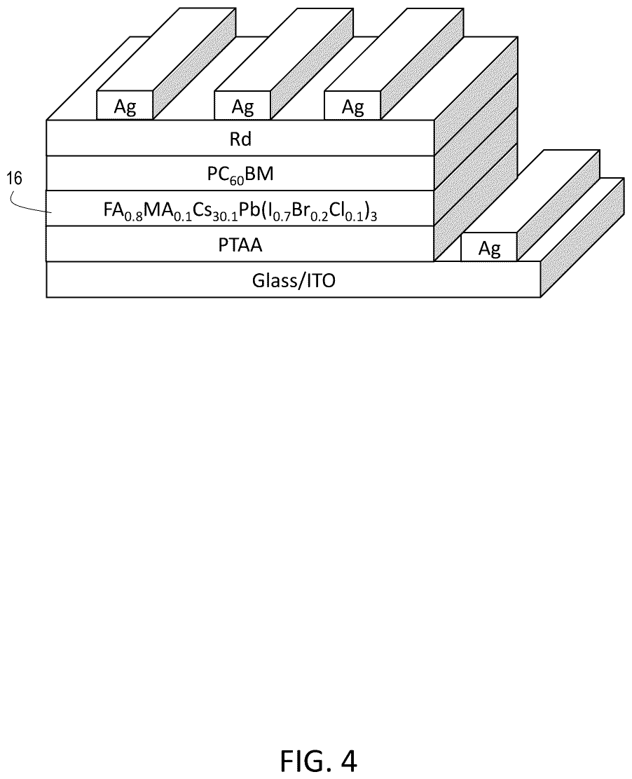

FIG. 4 is a schematic of the structure of a FA_{0.8} Cs_{0.2}Pb(I_{0.7}Br_{0.2} Cl_{0.1})₃ perovskite (2 eV) front cell.

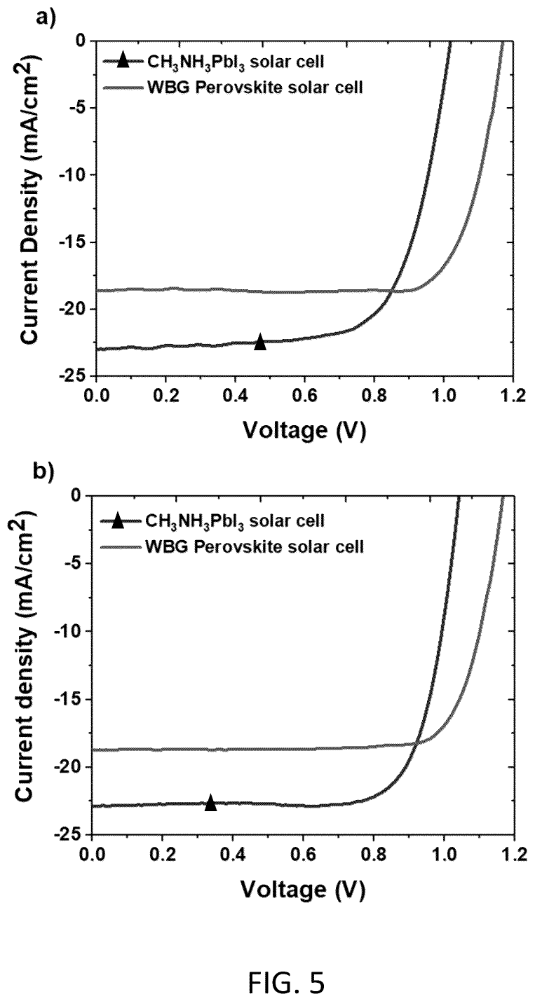

FIG. 5 is a graph of a) Forward and b) Reverse scan of the most common MAPbI₃, and WBG perovskite single junction solar cells and their photovoltaic parameters with cell efficiency at 17.17%, and 18.12%, respectively.

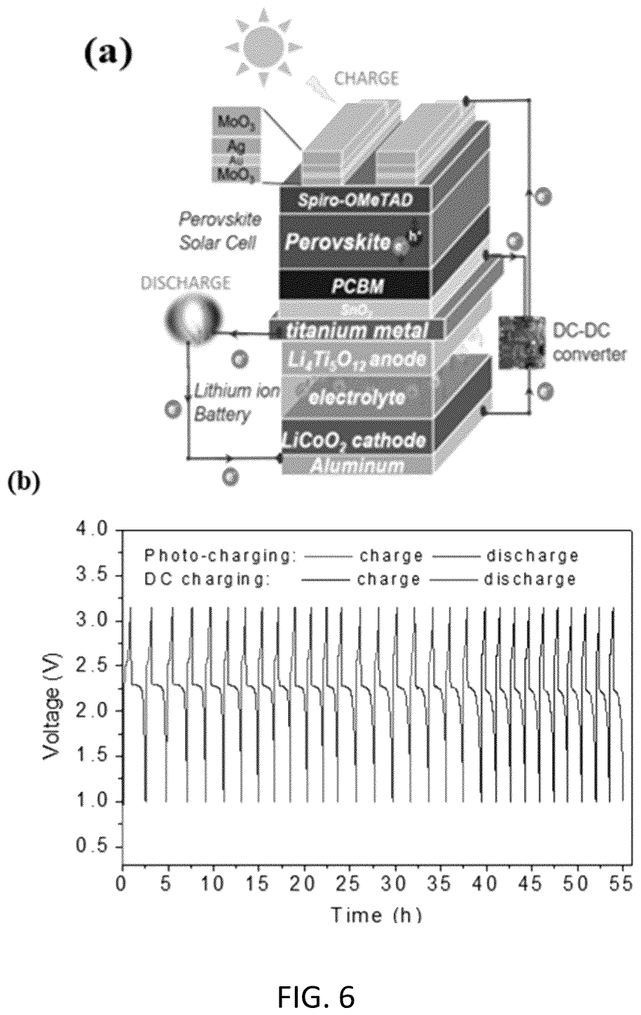

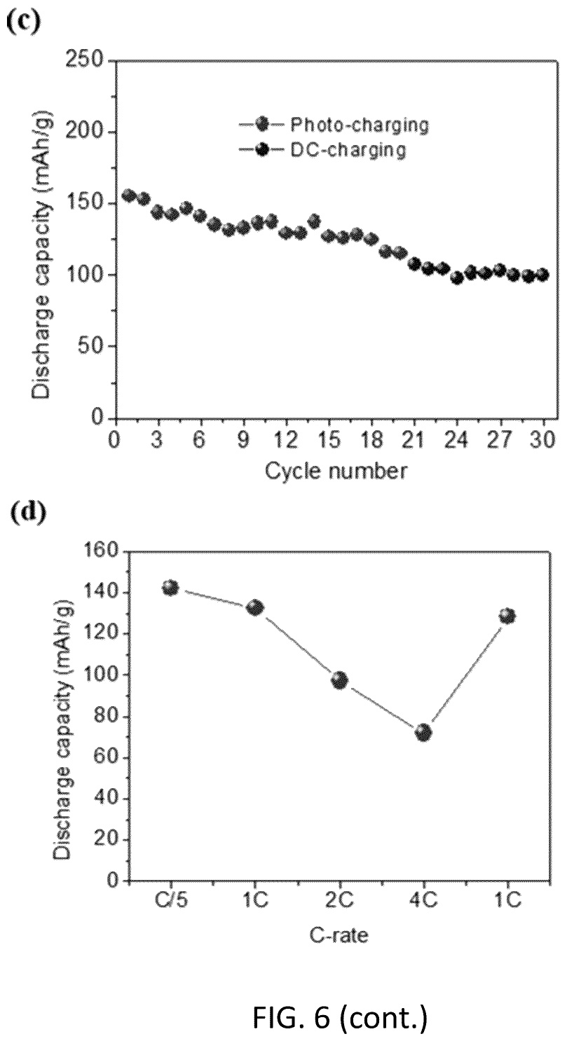

FIG. 6 is a schematic and series of graphs of the photo-charge and discharge cycling performance of rear illuminated perovskite solar cell with intrinsically integrated storage.

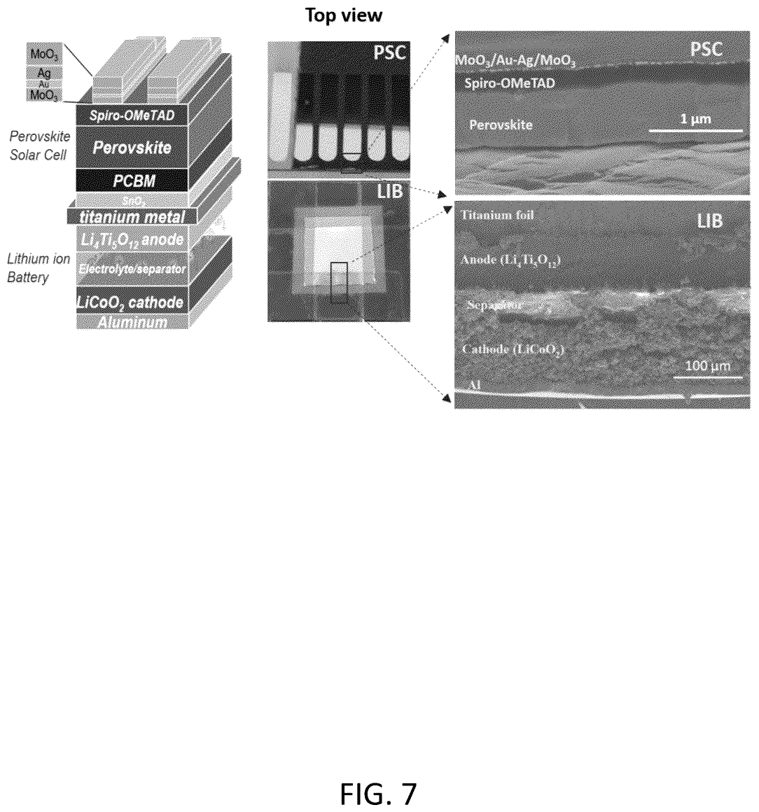

FIG. 7 is a schematic and series of images of a rear illuminated perovskite solar cell with intrinsically integrated storage, as follows: a) Device schematic. Digital images of b) PSC and c) LIB fabricated on either side of the titanium foil. Cross-sectional SEM images of d) PSC and e) LIB.

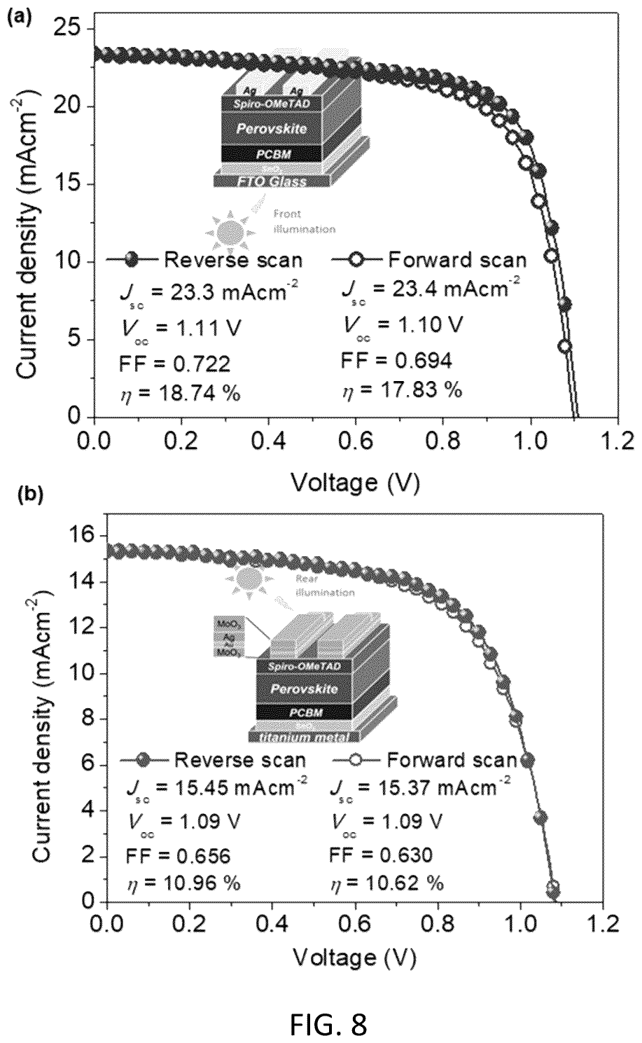

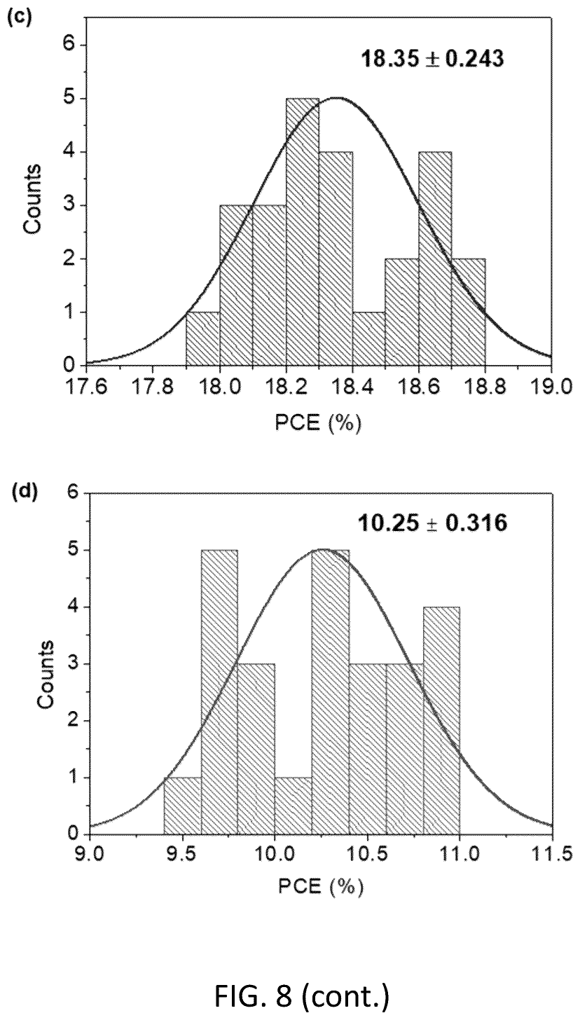

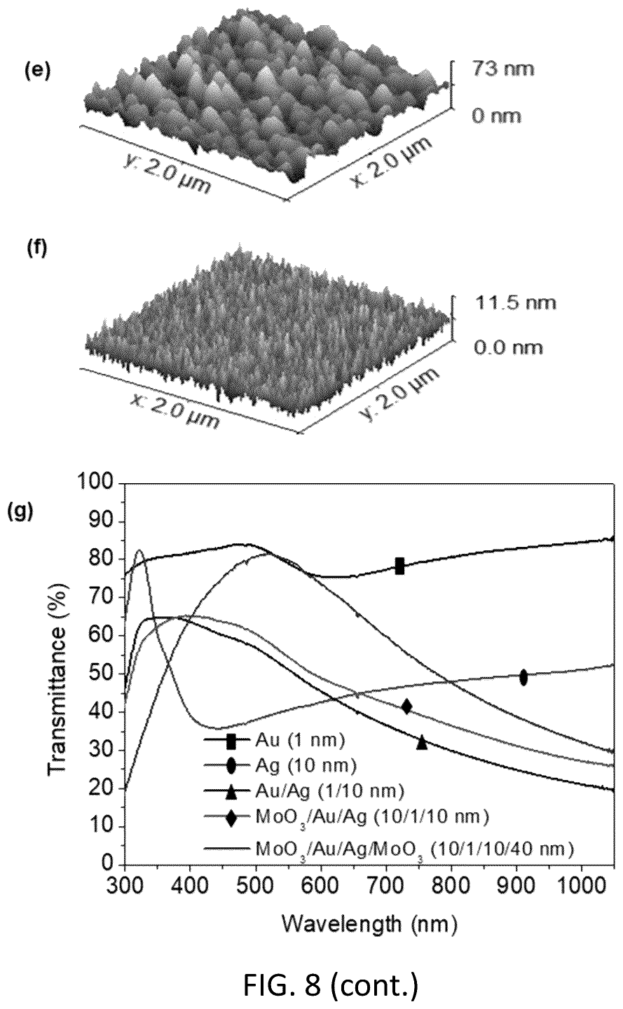

FIG. 8 is a series of graphs of the photovoltaic performance of PSCs, as follows: a) Front illuminated J-V curves of PSC on FTO glass (Inset shows device structure). b) Rear illuminated J-V curves of PSC on Ti metal (Inset shows device structure). c) Statistics of power conversion efficiency (PCE) of PSCs on FTO glass for 25 devices. d) Statistics of PCE of PSCs on Ti metal for 25 devices. AFM topography 3D-views of e) Ag and f) Au/Ag films. g) Optical transmittance of the DMD electrode with different layers.

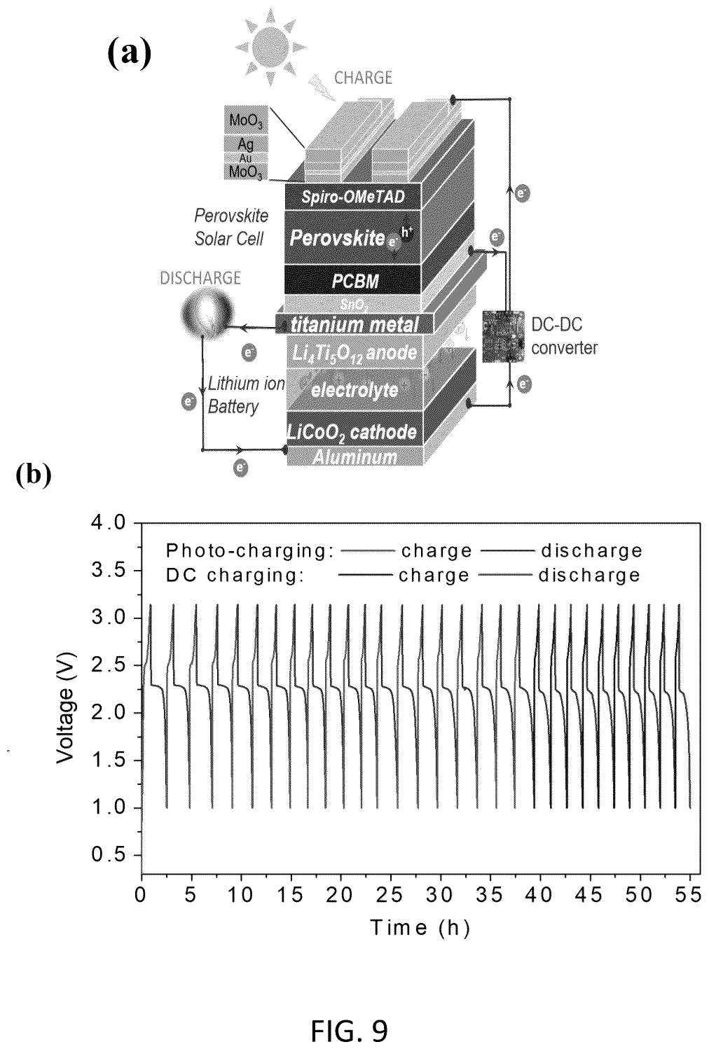

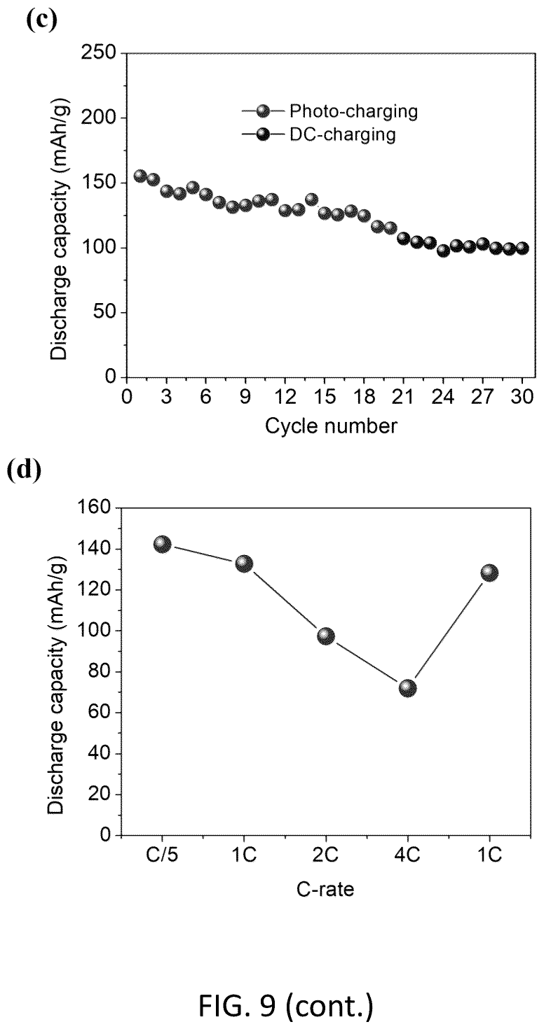

FIG. 9 is a schematic and series of graphs of the hoto-charge and discharge cycling performance of rear illuminated perovskite solar cell with intrinsically integrated storage. a) Device operation schematic. b) Voltage profiles of Li₄Ti₅O₁₂-LiCoO₂ battery: PSC-charging/discharging: green and red lines 1^{st}-20^{th} cycles; DC supply charging/discharging: blue and red lines 21^{st}-30^{th} cycles. c) Discharge capacity over number of charge/discharge cycles. d) Rate capability.

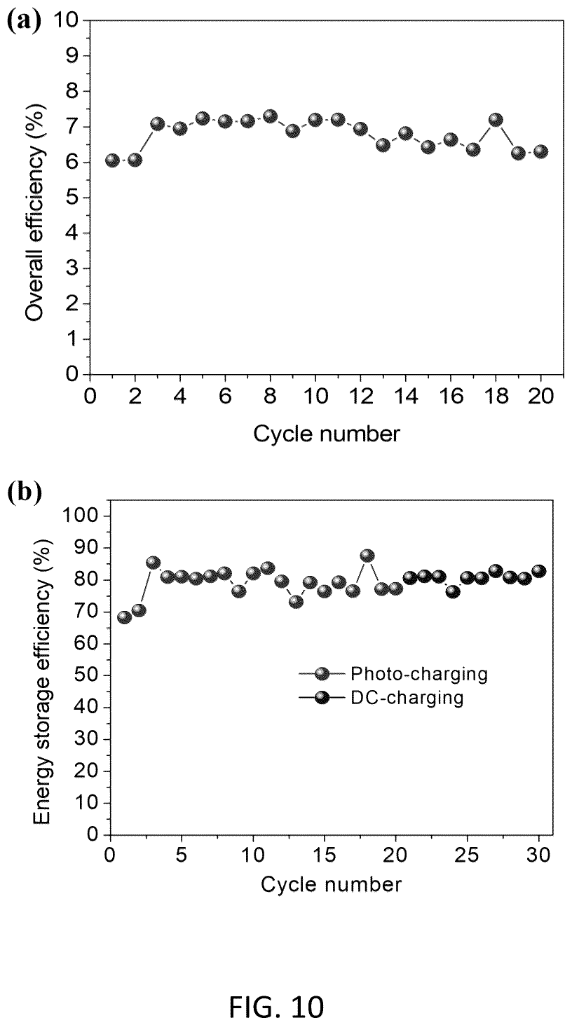

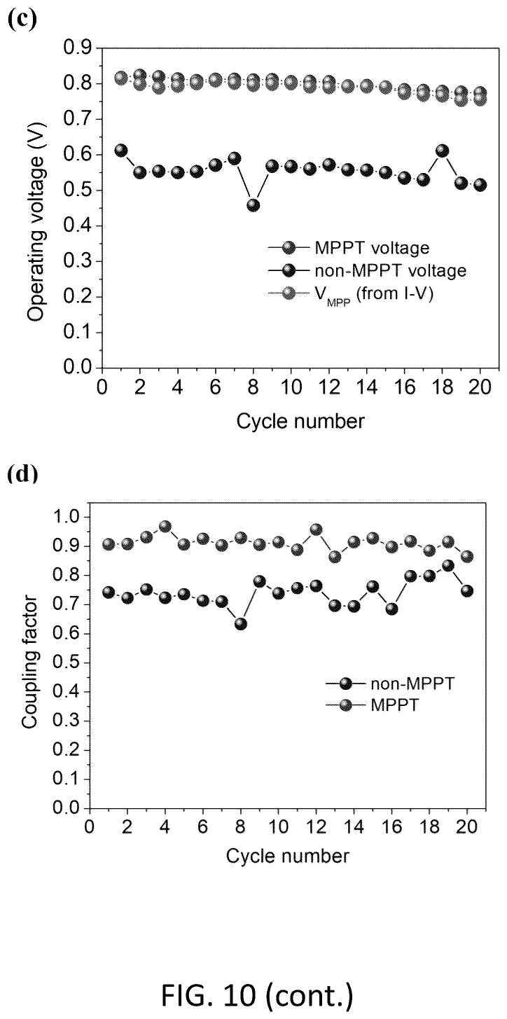

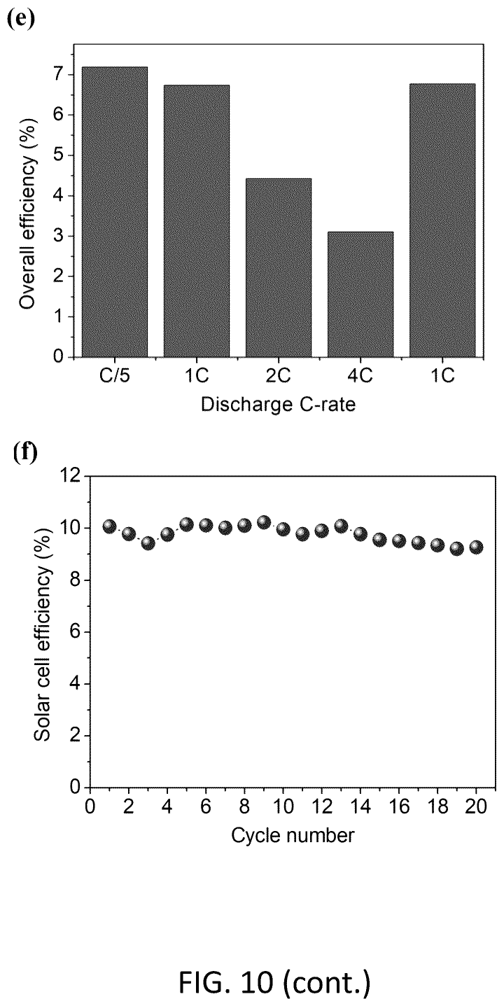

FIG. 10 is a series of graphs of the efficiency and maximum power point performance of rear illuminated perovskite solar cell with intrinsically integrated storage, as follows: a) Overall photoelectric conversion-storage efficiency of photo-charging/discharging. b) Energy storage efficiency of photo-charging and DC charging. c) Operating voltage vs cycle number. d) PV-battery coupling factor during the battery charging. e) Variation of overall photoelectric conversion-storage efficiency as a function of discharge C-rate. f) Variation of PSC efficiency with cycle number.

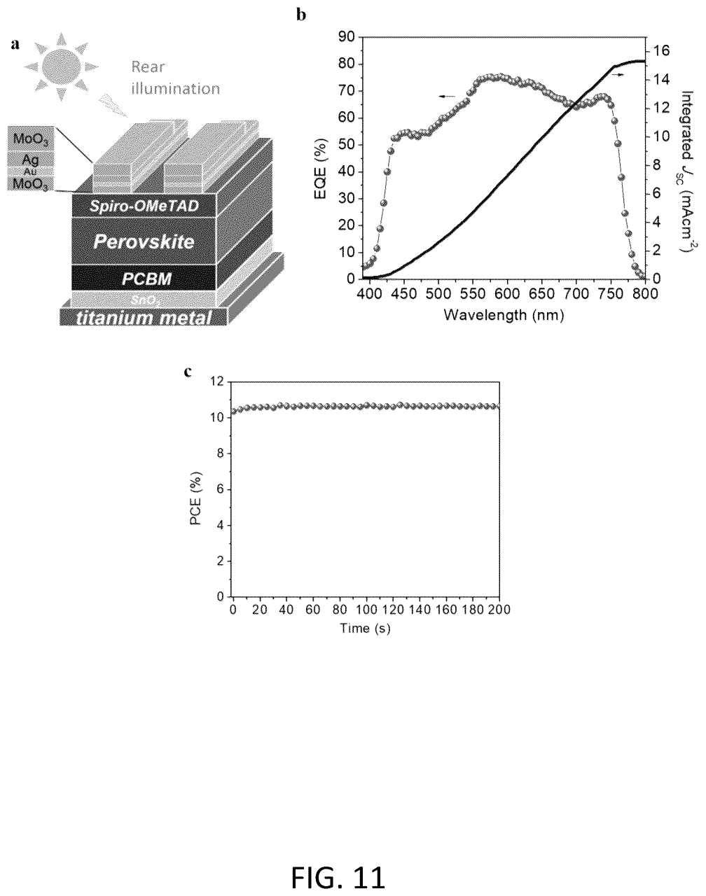

FIG. 11 is a schematic and series of graphs of a planar PSC on titanium metal substrate with DMD structure as top electrode, illuminated from the DMD side. a) Device schematic; b) EQE spectrum and integrated J_{SC}; c) Stabilized power output at maximum power point.

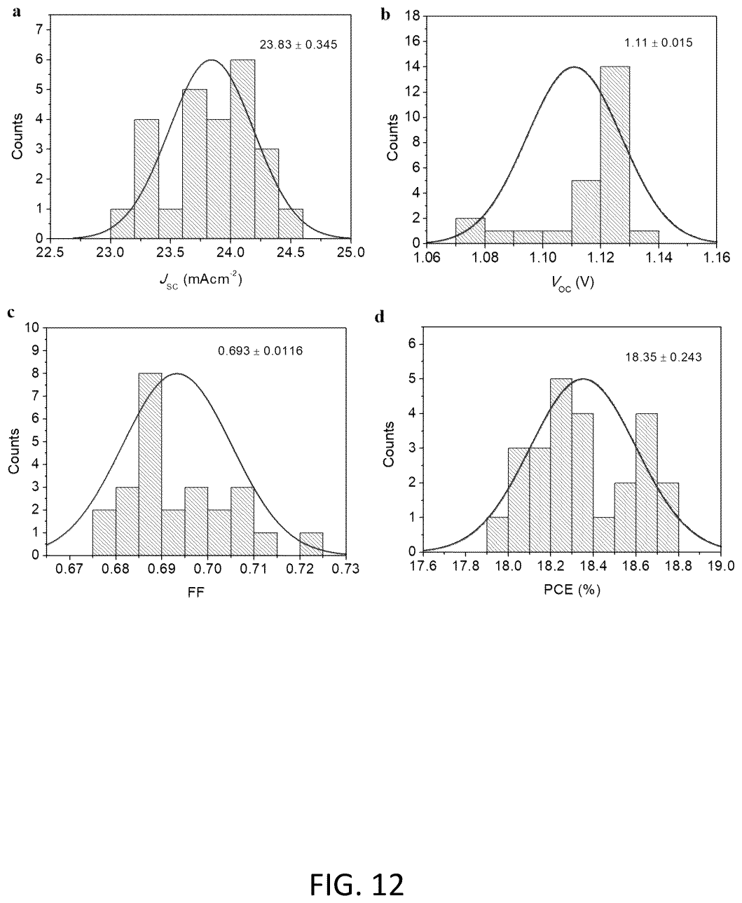

FIG. 12 is a series of graphs of the statistics of photovoltaic parameters of PSCs with FTO as bottom and Ag as top electrodes illuminated from FTO side for 25devices. a) J_{SC}; b) V_{OC}; c) FF; d) PCE.

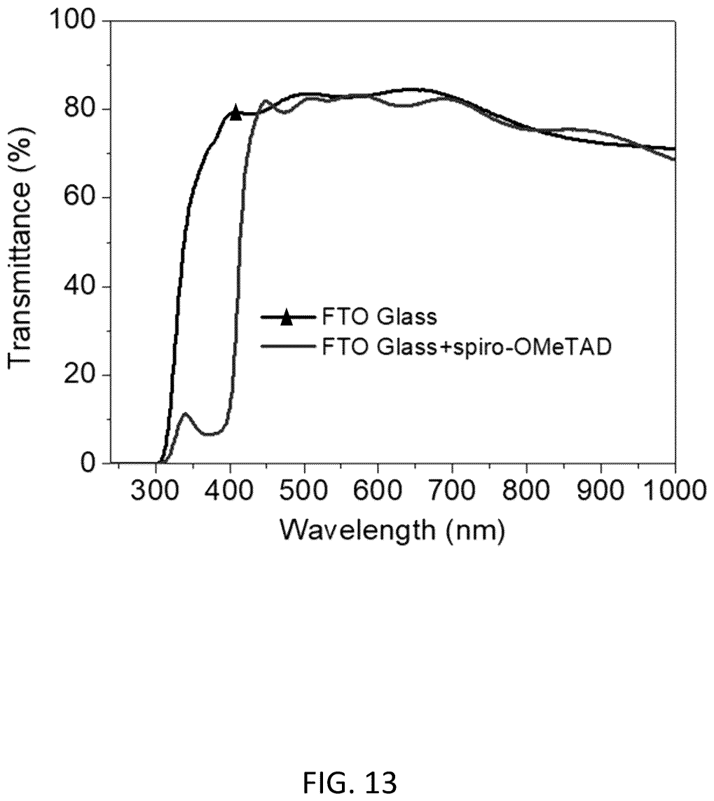

FIG. 13 is a graph of the transmission spectra of FTO coated glass and spin-coated spiro-OMeTAD on top.

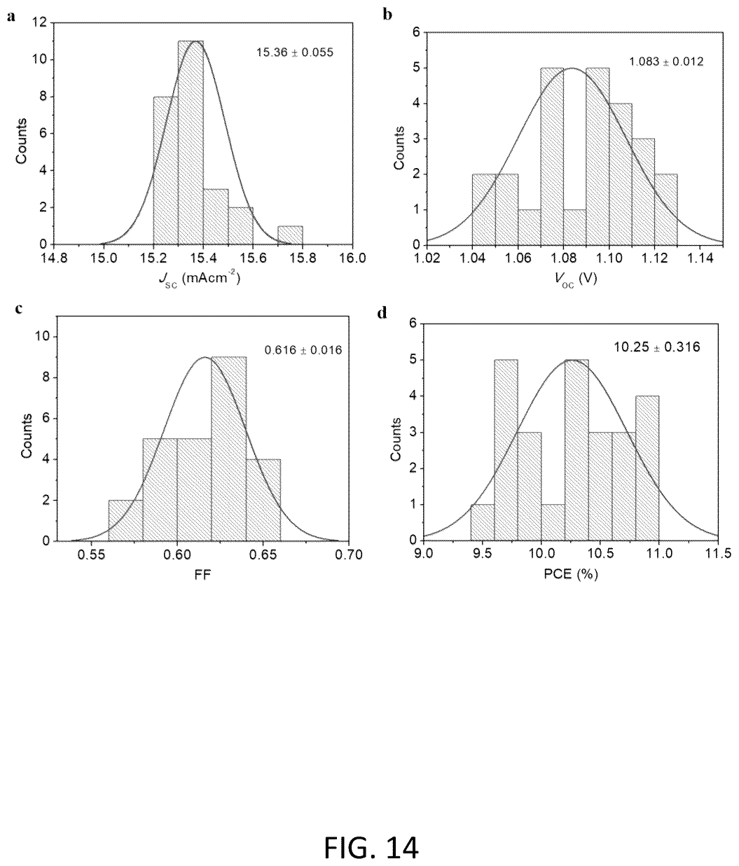

FIG. 14 is a series of graphs of the statistics of photovoltaic parameters of PSCs with Ti as bottom and DMD as top electrodes for 25 devices. a) J_{SC}; b) V_{OC}; c) FF; d) PCE

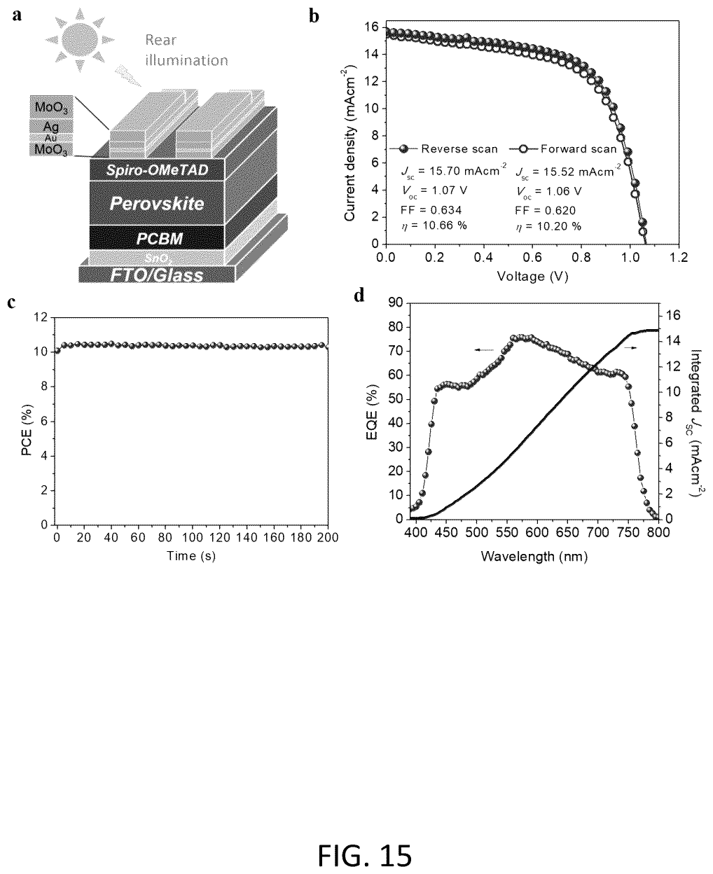

FIG. 15 is a schematic and series of graphs of Semi-transparent PSC on FTO substrate and DMD as top electrode, illuminated from the DMD side. a) Device schematic; b) J-V curves under front and rear illumination of 100 mWcm⁻² AM1.5 illumination; c) Stabilized power output at maximum power point; d) EQE spectrum and integrated J_{SC}.

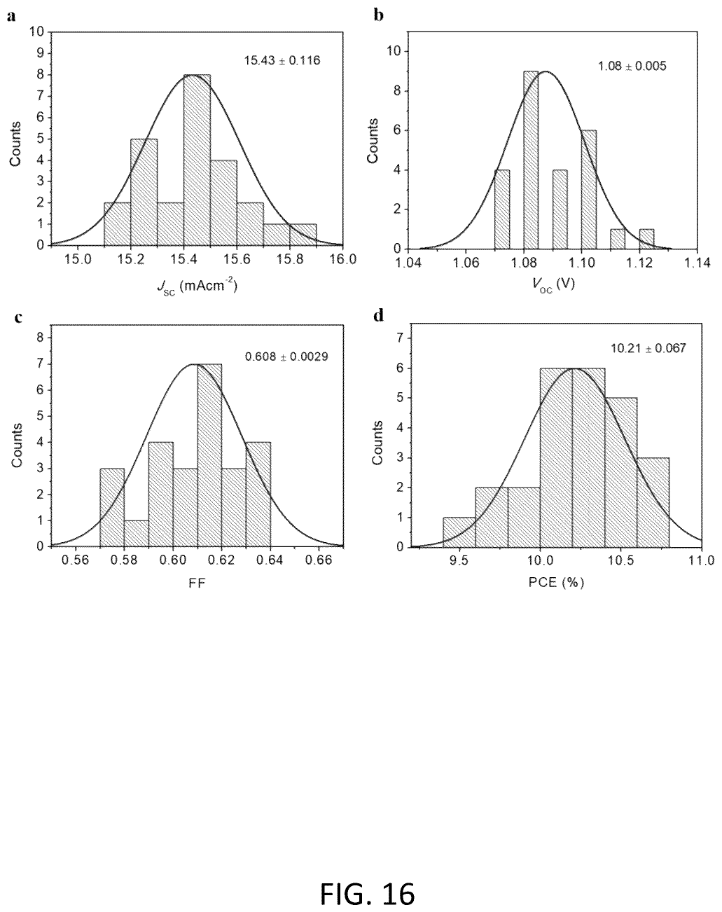

FIG. 16 is a series of graphs of the statistics of photovoltaic parameters of PSCs with FTO as bottom and DMD as top electrodes for 25 devices. a) J_{SC}; b) V_{OC}; c) FF; d) PCE.

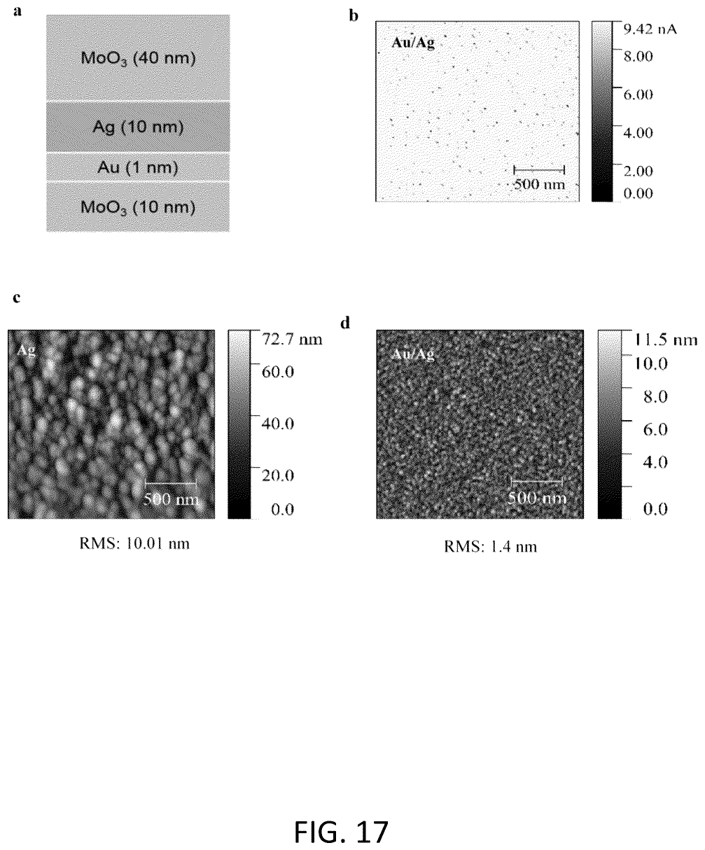

FIG. 17 is a series of graphs of semi-transparent DMD top electrode for PSC. a) Thickness of the different layers in DMD structure; b) CS-AFM image of Au/Ag film; AFM topography images (c) Ag and (d) Au/Ag.

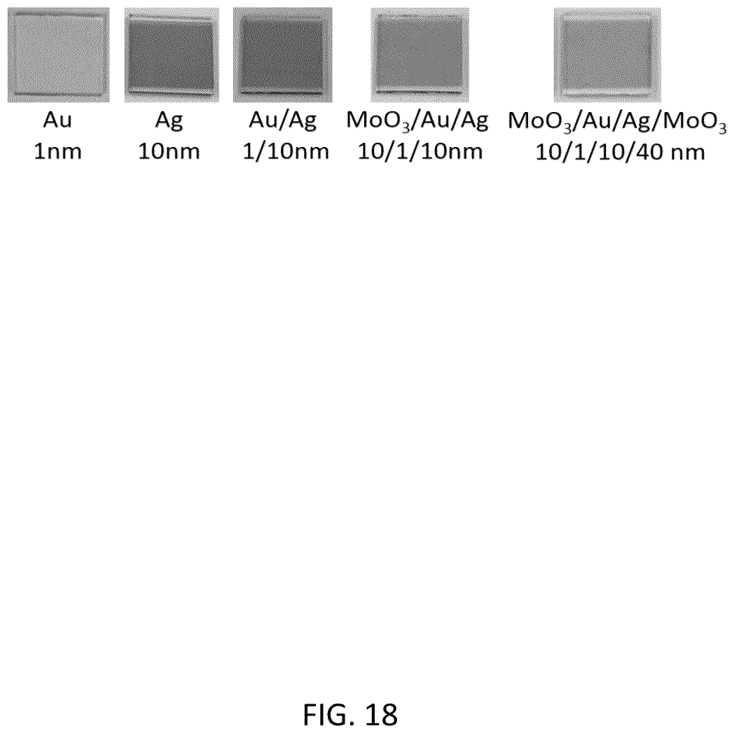

FIG. 18 is a series of photo images of the different layers of the semi-transparent DMD electrode.

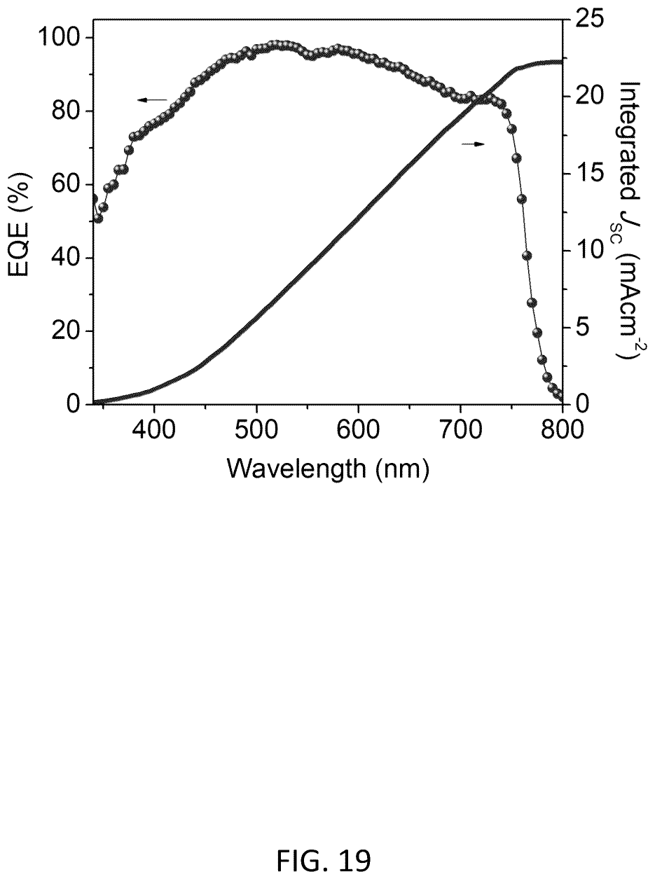

FIG. 19 is a graph of the EQE spectrum and integrated J_{SC} of PSC with FTO as bottom and Ag as top electrodes illuminated from FTO side.

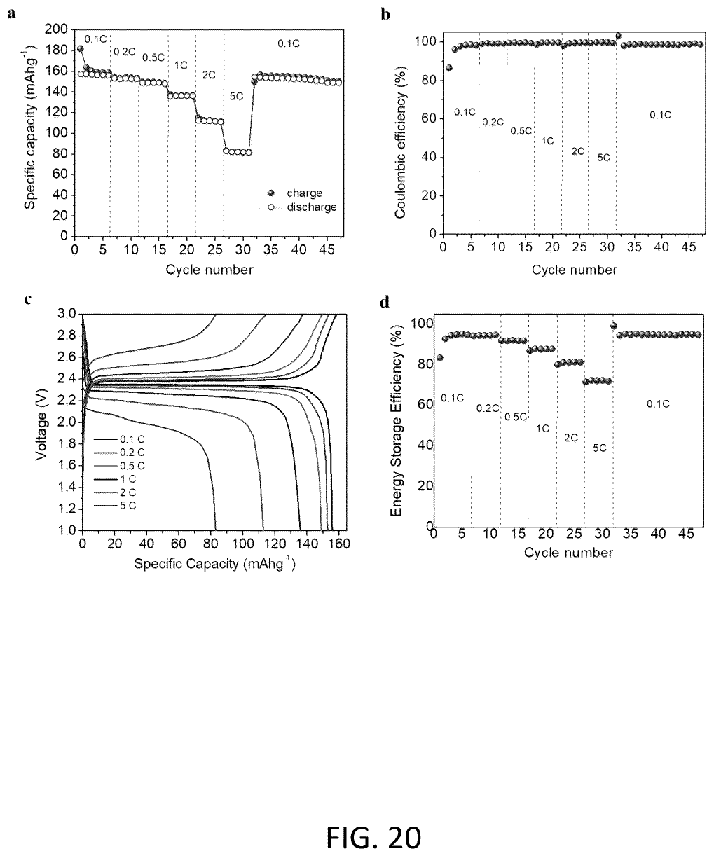

FIG. 20 is a series of graphs of the electrochemical cycling performance of Li₋₄Ti₅O₁₂/LiCoO₂ full cell, as follows: a) Rate capability curve; b) Coulombic efficiency. Rate performance of Li₄Ti₅O₁₂-LiCoO₂ full cell: (c) Charge/discharge voltage curves, (d) Energy storage efficiency.

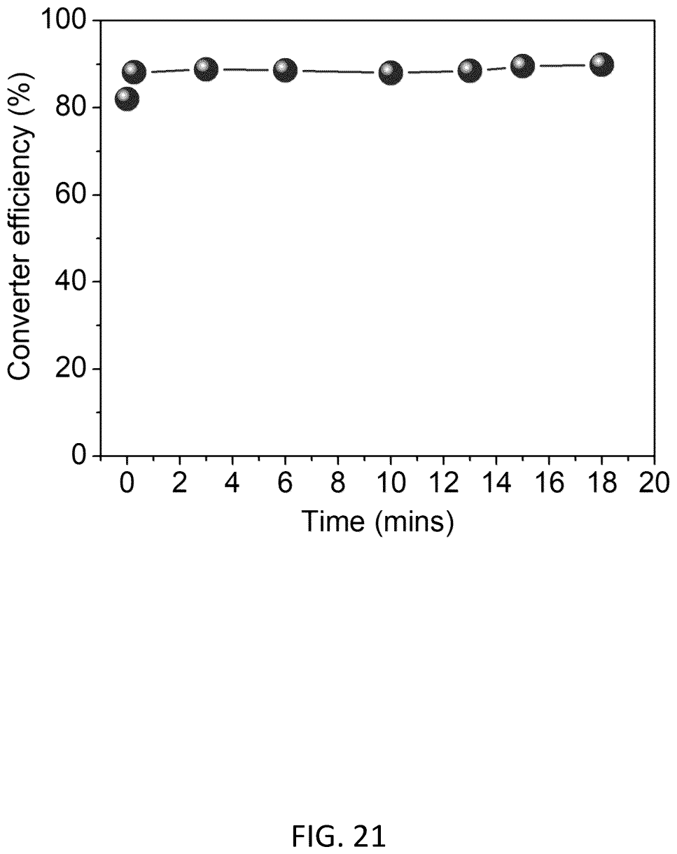

FIG. 21 is a graph of the variation of converter efficiency with charging time.

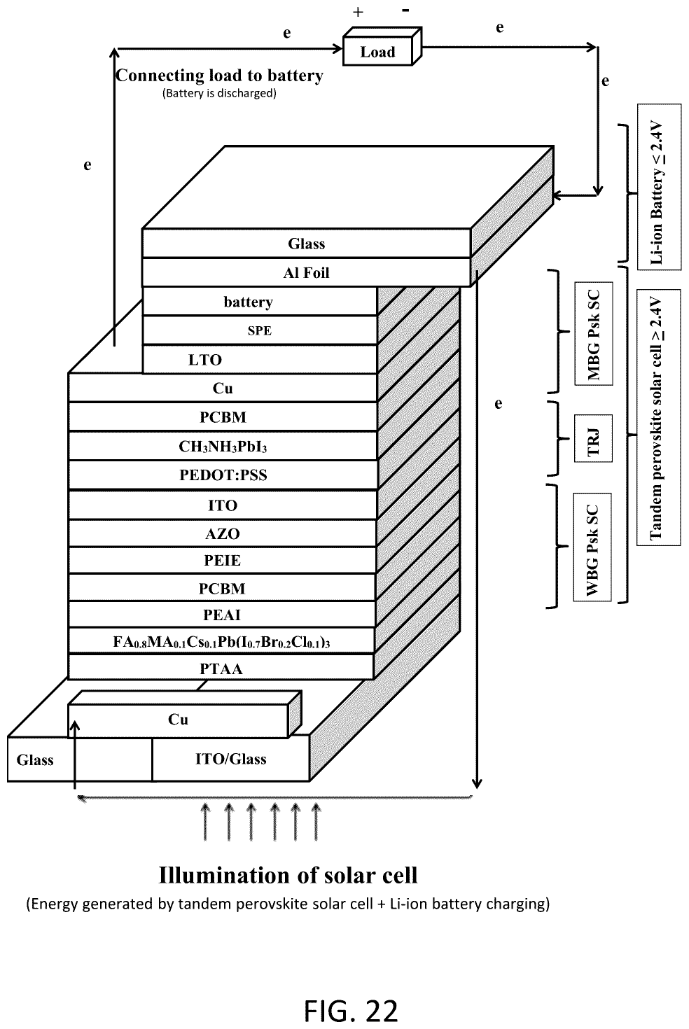

FIG. 22 is a schematic of the general structure of a solar battery with built-in monolithic tandem.

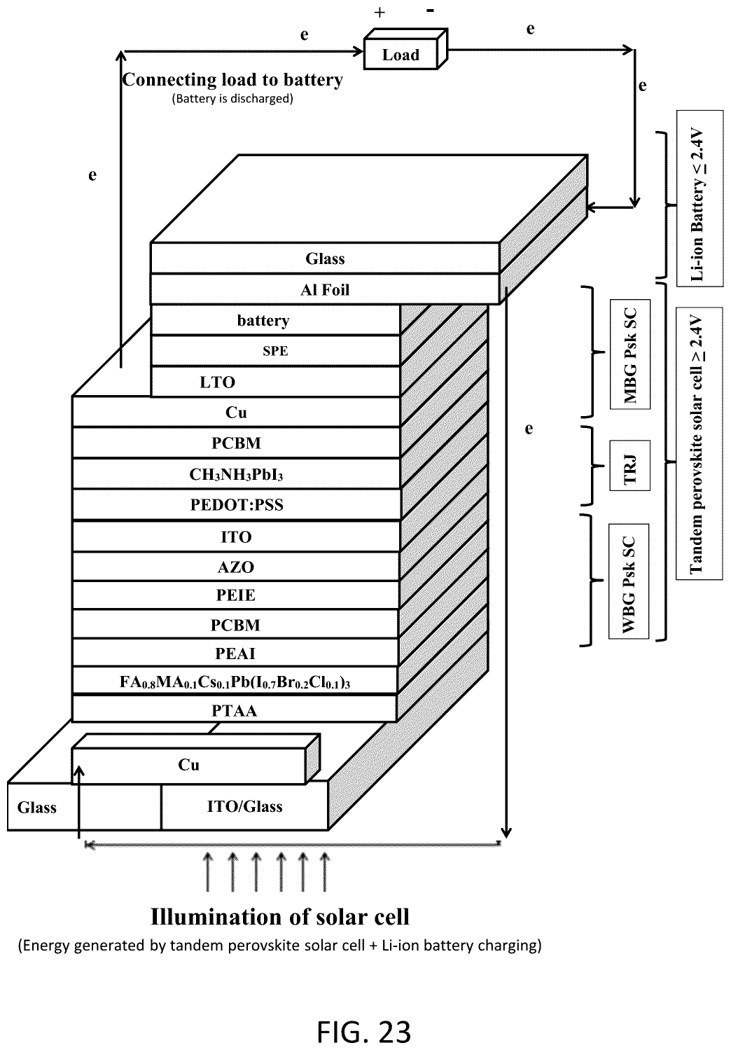

FIG. 23 is a schematic of the general structure of a solar battery with built-in triple junction solar cell.

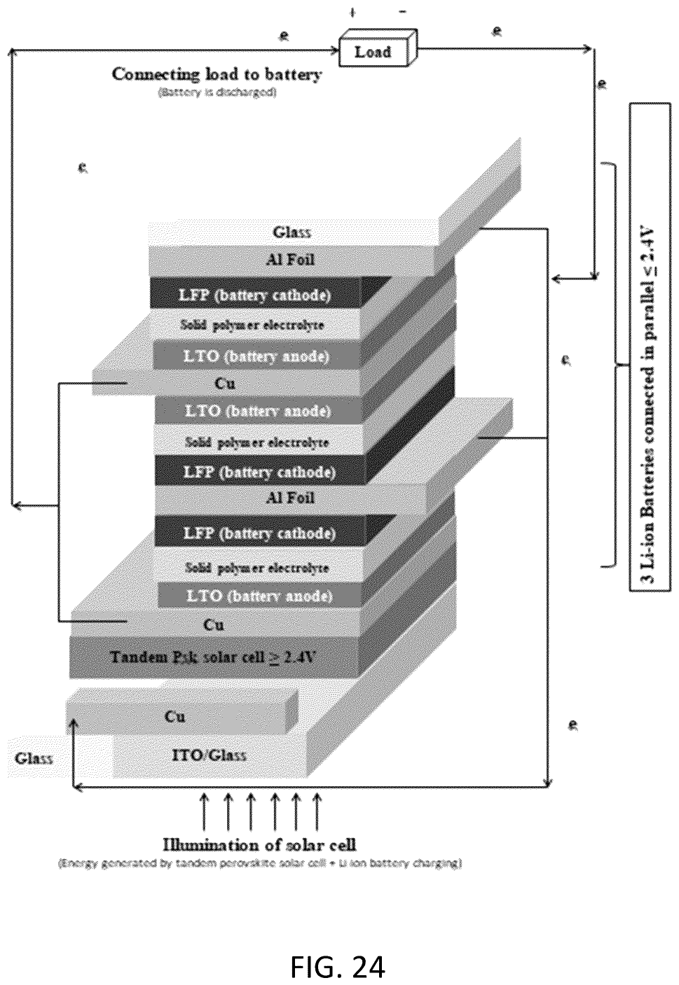

FIG. 24 is a schematic of a tandem PSC integrated 3 LTO-LFP LIBs connected in parallel.

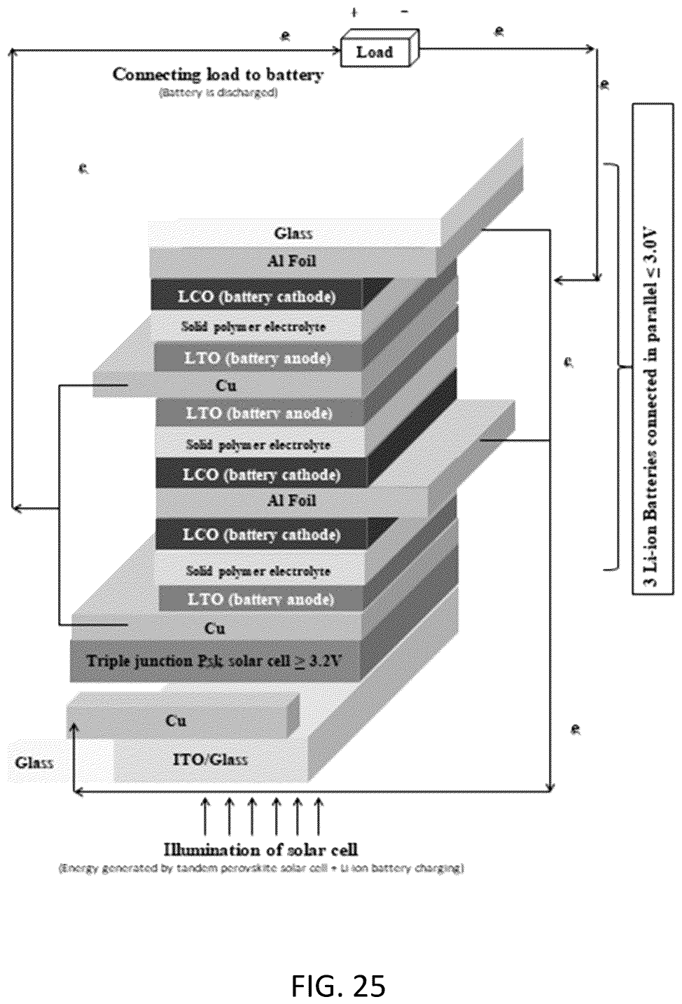

FIG. 25 is a schematic of a triple junction PSC integrated 3 LTO-LCO LIBs connected in parallel.

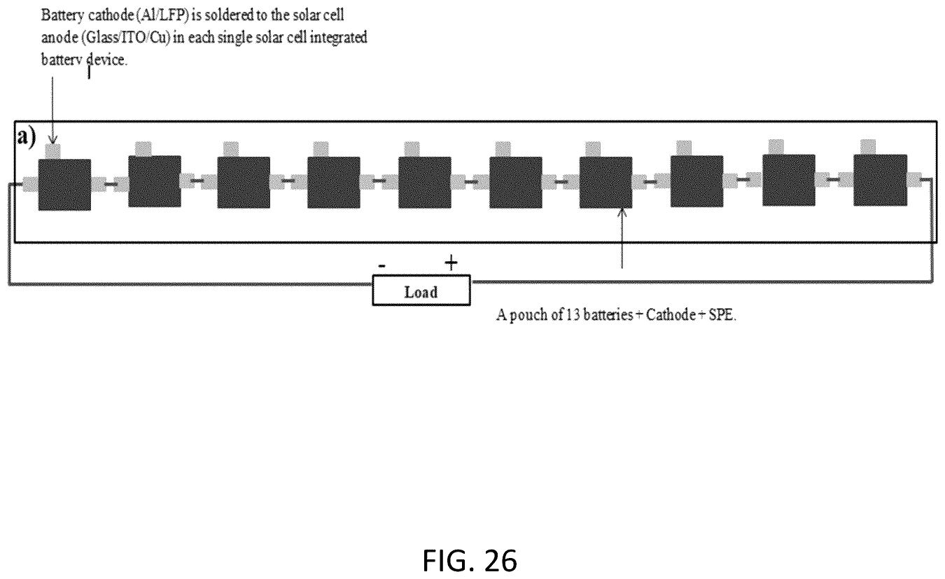

FIG. 26 is a schematic of solar batteries connected in series.

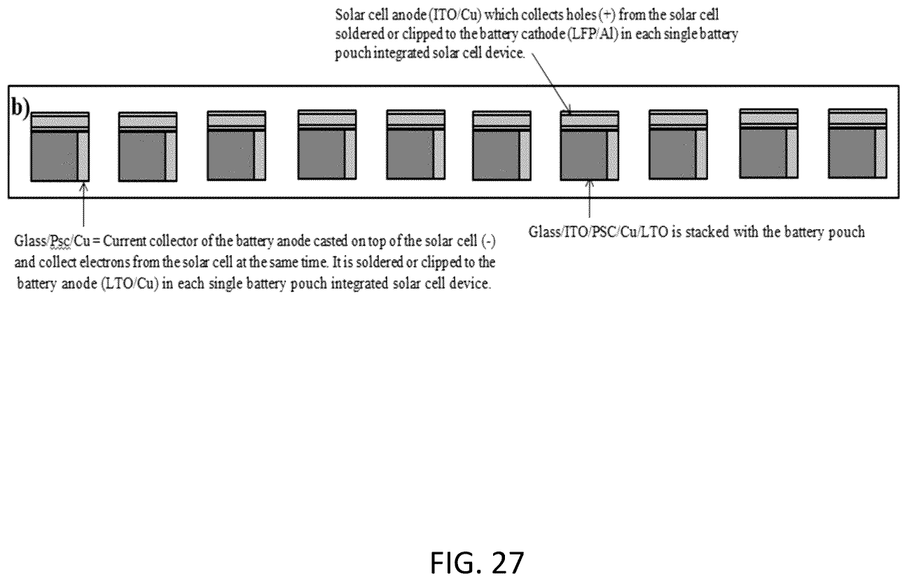

FIG. 27 is a schematic of battery anodes casted on top of monolithic multijunction solar cells.

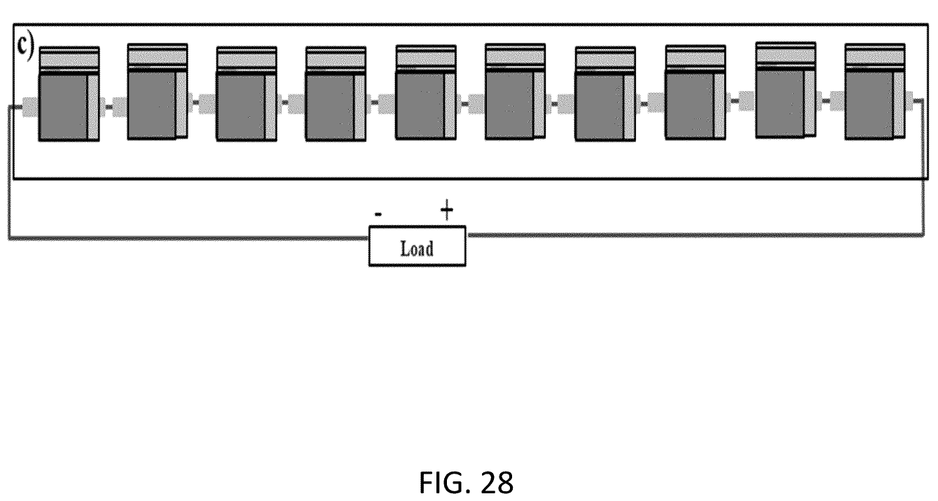

FIG. 28 is a schematic of a module of large area multijunction solar cells integrated batteries connected in series.

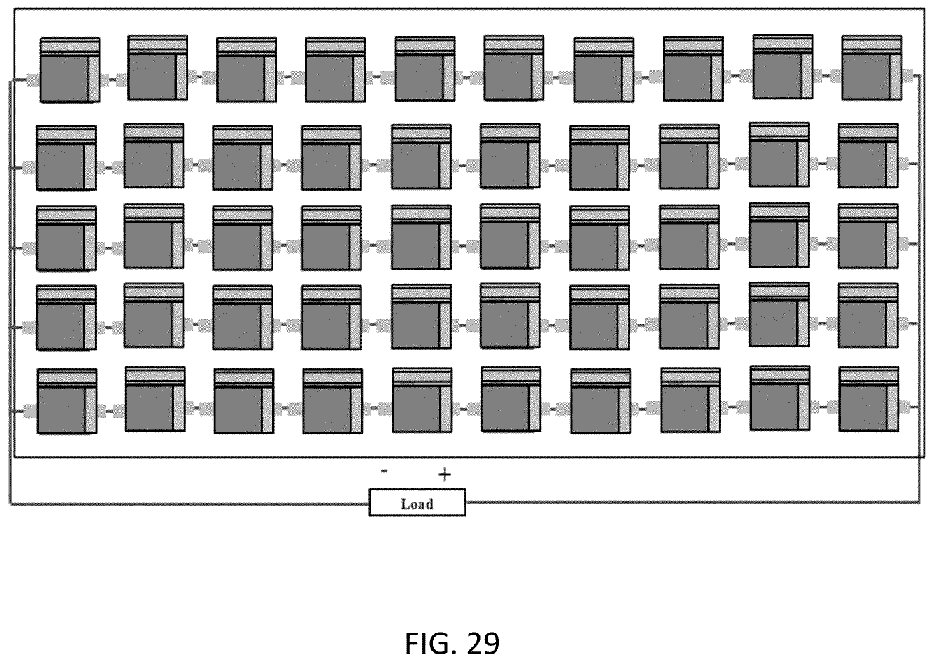

FIG. 29 is a schematic of the prepared modules integrated in parallel to form a solar battery panel with built-in PVs.

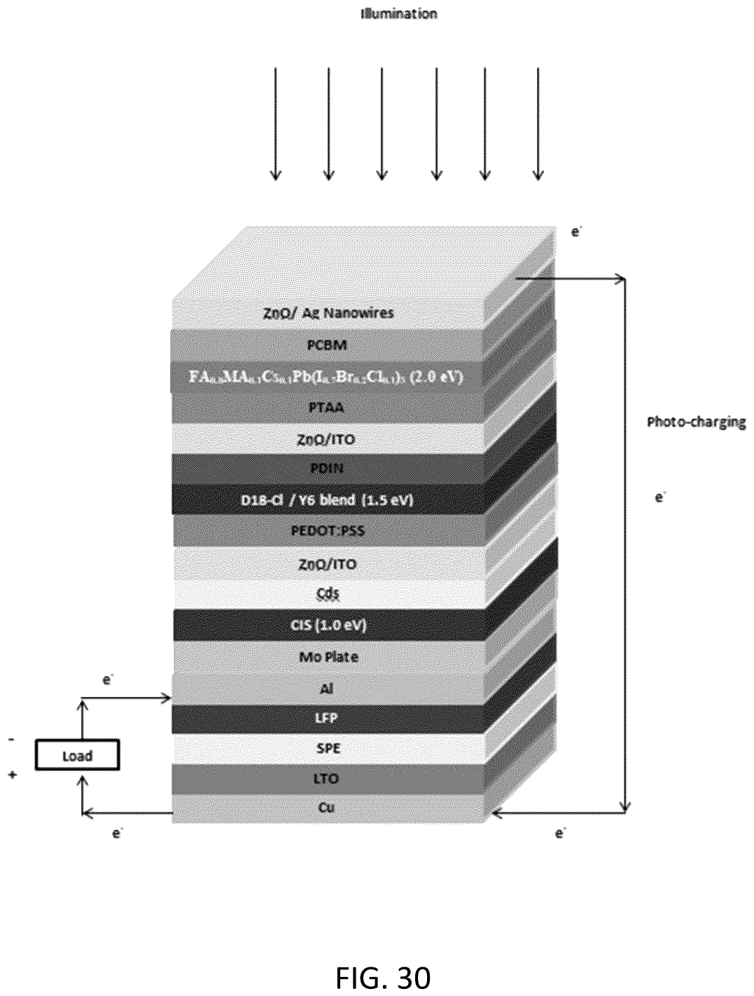

FIG. 30 is a schematic of a silicon or CIS/Polymer/Perovskite multijunction solar cell intrinsically integrated Li-ion battery.

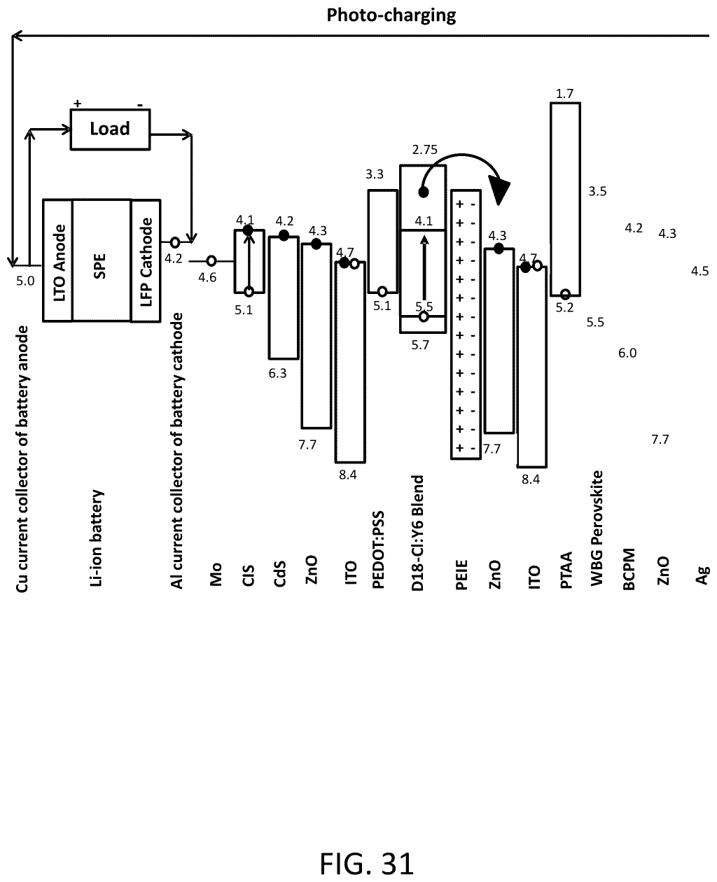

FIG. 31 is an energy level diagram of Silicon or CIS/Polymer/Perovskite multijunction solar cell intrinsically integrated Li-ion battery.

### DETAILED DESCRIPTION OF THE INVENTION

Referring to the figures, wherein like numerals refer to like parts throughout, there is seen in FIG. 1 a monolithic triple junction solar battery 10 made of absorbing materials with different bandgaps: crystalline silicon c-Si (1.1 eV) 12 as low bandgap, CH₃NH₃PbI₃ perovskite (1.55 eV) 14 as medium bandgap, and FA_{0.8}MA0.1 Cs_{0.1}Pb(I_{0.7}Br_{0.2} Cl_{0.1})₃ perovskite (2.0 eV) 16 as wide bandgap to decrease thermalization loss. The subcells are connected monolithically in series via optimized tunnel recombination junctions through which electrons and holes from the connected subcells can recombine. The generated voltage from triple junction solar cells is high enough to photo-charge an economic integrated all-solid-state Li battery 12. Alternatively, solar battery may include a double junction solar cell formed from two perovskite cells, as explained herein.

The intrinsic integration of the battery with solar cell enables using of a single device without an external cable connection, thus facilitate and decrease the installation cost. This new product can solve the challenges of the intermittent sun irradiation. The photovoltaic cell will be optimized to generate a current and voltage high enough to photo-charge the integrated battery at 0.5-1.0 C-rate. In a PV device, the absorber harvests photons with energy no less than its bandgap. Multijunction solar cells split the solar spectrum into parts as it contains multiple absorbers, each responsible for a section of the solar spectrum, thus minimizes the amount of thermalization loss. The monolithically integrated multijunction solar cells have two terminal electrodes (sub-cells are connected in series on a single substrate; all layers are sequentially deposited on top of one another). The main goal of monolithic integration is to surpass the Shockley-Queisser limit of solar cell power conversion efficiency (PCE) and obtain compact photovoltaic device with high photovoltage and low-cost roll-to-roll manufacturing.

Perovskite solar cells (PSCs) are attractive as top cells with medium or large bandgap for tandem and multijunction structure in which c-Si is used as low bandgap bottom cells 12. Use of a heterojunction c-Si bottom cell 12 is of appeal due to its high PCE and long-term stability. To improve light trapping in the c-Si bottom subcell 12, it is preferred to create double-side textured structure on a c-Si wafer and then combine it with a solution-processed micrometer-thick perovskite top subcell.

As seen in FIG. 1, monolithic triple junction solar cell 10 includes a front subcell made of wide bandgap (2.0 eV) perovskite FA_{0.8}MA0.1 Cs_{0.1}Pb(I_{0.7}Br_{0.2} Cl_{0.1})₃ 16which converts the blue portion of solar spectrum while transparent to the electromagnetic spectrum with medium and low energy. The middle subcell is a CH₃NH₃PbI₃ perovskite absorber 14 with medium bandgap (1.55 eV). The rear subcell uses a heterojunction c-Si (fully textured) 12 with a narrow bandgap (1.1 eV) to convert low energy portion of the solar spectrum. The three subcells 12, 14, 16 are connected by transparent tunnel recombination junctions (TRJ) to decrease electrical resistance and optical loss, prevent photovoltage and photocharge generation between subcells, allow current in one direction, and facilitate electrons tunneling between barriers.

In triple junction solar cell 10, the wide bandgap FA_{0.8}MA_{0.1} Cs_{0.1}Pb(I_{0.7}Br_{0.2} Cl_{0.1})₃ front subcell 16 will deliver a voltage output of 1.4V, the middle CH₃NH₃PbI₃ subcell 14 will generate a voltage output of 1.0V, and the heterojunction c-Si subcell 12 will produce a 0.7V voltage. As these subcells are connected in series, the overall triple junction solar cells will deliver a voltage output of 3.1V. To fabricate a multijunction using perovskite as the middle and rear subcells, orthogonal solvents may be used as they will not wash away the underlying layers as some perovskites are sensitive to polar solvents and organic solvents.

The three subcells are integrated monolithically via newly engineered TRJs. The sputtered transparent indium tin oxide (ITO) 18 on top of the a-Si:H (n) 20 will act as a TRJ for c-Si rear 12 and CH₃NH₃PbI₃ middle subcell 14, while PEIE/AZO/ITO 22 will be utilized as a TRJ between middle and front perovskite subcells through which the generated electrons and holes from neighboring subcells can recombine. Here, PEIE is Ethoxylated poly-ethylenimine (PEIE) and AZO is aluminum-doped zinc oxide.

A garnet/solid polymer electrolyte (SPE) composite 24 may be used as solid electrolyte for all-solid-state Li-ion battery to solve the issues of liquid electrolytes, such as safety and technical challenges including leakage, corrosion, flammability, and explosion. The garnet/SPE composite is used to replace conventional pure SPE solid electrolytes because SPEs have low ionic conductivity because they are semi-crystalline, where the crystalline regions hinder ion transport while the amorphous regions facilitate ion transport. SPEs have insufficient stability and are not compatible with the Li metal. This leads to side reactions, passivation layers, high interfacial impedance, and electrical shorting. Also, slow electron transfer during Li stripping results in voids at the Li surface, while uneven Li deposition results in dendrite growth. This causes volume changes on a Li metal surface. Li insertion in the cathode leads to volume changes on the cathode surface. Such volume changes at electrodes result in stresses at electrolyte/electrode interfaces, thus causing SPE degradation. In addition, limited mass transport of the electrolytes results in concentration gradient, passivation layers, ohmic voltage drop, and capacity fading. Fast cycling and high voltage cycling can cause cathode cracking, which decreases storage sites for Li intercalation and reduces the capacity.

Therefore, the present invention employs a garnet/solid polymer electrolyte composite for all-solid-state Li-metal or lithium-ion battery to deliver high specific capacity and energy density. To improve the specific capacity, cycling performance, and capacity retention of the battery, additives such as Tetrabutylammonium-hexaflourophosphate (TBA-HFP) may be used to improve the ionic conductivity and stability of the solid electrolyte and cathode, as well as enhance the electrolyte/electrodes interfacial stability. The Li+ cation transport within the electrolyte may be accelerated by a Lawsone additive, as it is able to coordinate reversibly with the generated Li+ cations facilitating their transport within the electrolyte. The charge transfer from the current collectors to the electrodes may be enhanced via the additive TBA-HFP, which has weekly coordinating ions able to re-orientate under the influence of the applied electric field and accumulate onto their corresponding electrodes. Cathode stability may be enhanced via its surface coating with Al(PF₆)₃ to achieve physical protection and prevent cracking of the cathode, thus increase storage sites for Li+ cation intercalation inside the cathode. A thin film battery may thus be assembled and then integrated to the optimized triple junction solar cell to form monolithic triple junction solar battery 10.

Solar battery 10 according to the present invention should deliver greater than 30% solar-to-electricity efficiency, which can photo-charge a Li battery at 0.5-1 C, 1000 cycles at 80% capacity retention, and 25° C. for 300 mAhg⁻¹ specific capacity and 150 Ah/m² areal capacity density. The present invention thus provides a compact, lightweight, and low-cost solar energy generation and storage system in a single device with an overall efficiency that is greater than or equal to 30% and has an energy density of 450 Wh/kg while being photo-rechargeable by sun. For the residential, commercial, and utility scale applications, the present invention may be scaled up and connected in series and parallel as a panel that can generate high voltage and power based on the load demand.

### Fabrication, Characterization, and Testing of High Performance Triple Junction c-Si/Perovskite/Perovskite Solar Cell

### Fabrication of Rear Low Bandgap (1.1 eV) heteRojunction c-Si Subcells

Surface passivation is applied to achieve high performance c-Si solar cells, where an amorphous silicon will passivate the c-Si film and prevent recombination from the metallic electrode. Heterojunction c-Si technology made of a n-type crystalline silicon (c-Si) and a p-doped amorphous silicon (a-Si) may be used. Amorphous Si is highly defective, and hydrogenation will be performed to decrease defects. The n-doped c-Si wafer is a float zone double side wafer (c-Si, n-doped, thickness 250-280 μm), which will be textured in alkaline solution to get randomly distributed pyramids on two sides, followed by cleaning in RCA1 H₂O₂-NH₄OH-H₂O solution to remove organic residues and RCA2 H₂O₂-HCl-H₂O solution to remove metal ions. The size of the pyramids will be controlled by adjusting the alkaline concentration and the process temperature. After that, the wafers will be dipped in 5% hydrofluoric acid solution to remove the native oxide layer. Hydrogenated intrinsic amorphous Si a-Si:H (i) will be deposited on the two sides of the textured c-Si from a gas mixture of silane (SiH₄) and hydrogen (H) by plasma enhanced chemical vapor deposition (PECVD). The n-doped hydrogenated amorphous Si a-Si:H (n) will be deposited on one side of the Si wafer by doping the previously deposited intrinsic layer with Phosphine (PH₃) using PECVD. p-doped hydrogenated amorphous Si a-Si:H (p) will be deposited on one side of the Si wafer by doping the previously deposited intrinsic layer with trimethylborane (TMB) using PECVD. Indium tin oxide (ITO) will be sputtered on the two sides of the wafer, i.e., on top of the prepared a-Si:H (n) and a-Si:H (p) layers. FIG. 2 shows the structure of heterojunction Silicon.

The above procedures will be compared with the following solution processed procedures. 180 nm a-Si (i): Neopentasilane (NPS) will be oligomerized in a teflon apparatus by thermal treatment to an average molecular weight of approximately 2200 g/mol. Neopentasilane oligomers (NPOs) will then be dissolved in toluene and cyclooctane to form a 30 wt % solution. The solution will be spin coated and annealed at 440° C. for 60 s. 5-20 nm a-Si (n) (phosphorous doped) will be synthesized by addition of 5% P₄ to NPS which is oligomerized in a teflon apparatus by thermal treatment to an average molecular weight of approximately 1200 g/mol. A 20 wt % toluene/cyclooctane solution of the resulting n-doped NPO will be prepared and spin coated then annealed at 500° C. for 60 s. 5-20 nm a-Si (p) (Boron doped) will be synthesized by addition 1.5 at % BH₃THF to NPS which is oligomerized in a tefl on apparatus by thermal treatment to an average molecular weight of approximately 550 g/mol. A 3 wt % toluene/cyclooctane solution of the resulting p-doped NPO will be prepared, spin coated and annealed at 500° C. for 60 s. Optical, electrical, and morphological properties of all films and PV devices will be fully characterized as described in subtask 1.5.

### Fabrication of Middle Medium Bandgap (1.55 eV) CH₃NH₃PbI₃ Solar Cell

Perovskite solar cells will be fabricated on ITO substrates, which will be cleaned by sonication in detergent water, Deionized-water, acetone, and isopropanol for 25minutes each followed by oxygen-plasma treatment. A thin layer of PEDOT: PSS, will be spin coated at 4500 rpm for 1 minute on top of the ITO substrates followed by annealing at 120° C. for 20 minutes. Perovskite solution will be prepared from an equimolar mixture of 581mg PbI₂ and 209 mg CH₃NH₃I dissolved in a 1 mL mixture solvent comprising DMSO and γ-butyrolactone in 3:7 vol. ratio and stirred on a hotplate inside the glove box overnight at 70° C. The perovskite solution will be spin coated on top of PEDOT: PSS at 750 rpm for 20 seconds and then at 4000 rpm for 1 minute, which will be dripped with 160 μL toluene after 20 seconds during the second spinning step. The films will be annealed at 80° C. for 10 minutes. PC60BM solution with a concentration of 20 mg m⁻¹ in chlorobenzene will then be coated onto the perovskite layer at 2000 rpm for 40 seconds followed by annealing at 80° C. for 5 minutes. Rhodamine 101solution (0.5 mg m⁻¹ in isopropanol) will then be spin coated on top of [6,6]-phenyl C60 butyric acid methyl ester (PC₆₀BM) layer at 4000 rpm for 40 seconds inside glove box. Finally, 100 nm of silver will be deposited as a top electrode by thermal evaporation. FIG. 3 shows the structure of CH₃NH₃PbI₃ solar cell. Optical, electrical, and morphological properties of all films and PV devices will be fully characterized as described in subtask 1.5.

### Fabrication of Front Wide Bandgap (2 eV) FA_{0.8}MA_{0.1} Cs_{0.1}Pb(I_{0.7}Br_{0.2} Cl_{0.1})₃ Solar Cell

The wide bandgap absorber FA_{0.8}MA0.1 Cs_{0.1}Pb(I_{0.7}Br_{0.2} Cl_{0.1})₃ will be obtained by preparing mixed Br-I halides perovskite MAPbI₃₋ₓ Brₓ and adjusting their mixing ratio, so that the bandgap can be tuned from about 1.6 eV to 2.3 eV. Br ratios should not exceed 0.2 so that it does not affect device performance negatively by decreasing the open-circuit voltage (Voc) and fill factor (FF). Doping FA⁺ with a suitable amount of Cs⁺ reduces the Goldschmidt tolerance factor in the alloy materials and stabilizes the perovskite cubic structures. The FA-Cs alloys also have a lower tendency for halide segregation under illumination. Pb(SCN)₂ increases the grain size and crystallinity of WBG films. Dipolar MA⁺ cation and its reorientation heals deep traps in the perovskite film. Chlorine (Cl) alloying will be tested to increase the bandgap of I-Br mixed perovskites, enhance charge-carrier mobility and lifetime because of the reduction in the halogen vacancy defect density (compact and uniform films) via elemental compensation with the smaller Cl ions. PEAI solution acts as grain boundary passivation agent creating an ion diffusion barrier and reducing the accumulation of detrimental ionic defects at grain boundaries.

FIG. 4 shows the structure of WBG perovskite solar cell. Indium tin oxide (ITO) substrates will be cleaned by detergent, deionized water, acetone, and isopropanol for 30 min, respectively, and then blown dry with nitrogen gas. They will be treated by ultraviolet-ozone for 20 min and transferred to a N₂-filled glovebox. PTAA solution (2 mg Poly [bis (4-phenyl) (2,4,6-trimethylphenyl) amine] (PTAA) in 1 ml Chlorobenzene contain 1 wt % 2,3,5,6-Tetrafluoro-7,7,8,8-tetracyanoquino-dimethane (F4-TCNQ)) will be spin coated at 5000 r.p.m. for 30 s, followed by annealing at 100° C. for 10 min. WBG perovskite FA_{0.8} Cs_{0.2}Pb(I_{0.7}Br_{0.3})₃ solution will be prepared by adding 273.8 mg PbI₂, 178.4 mg PbBr₂, and 5.2 mg Pb(SCN ₂ will be dissolved in 0.750 ml DMF. 148.6 mg FAI, and 56.2 mg CsI will be dissolved 0.250 ml DMSO. The previous solutions will be stirred at 60° C. overnight and mixed before fabrication by 1 hr. Dipolar MA⁺ cation will be added into the perovskite precursor solution and optimized to prepare FA_{0.8}MA0.1 Cs_{0.1}Pb(I_{0.7}Br_{0.2} Cl_{0.1})₃ perovskite film. To enhance the wettability of the FA_{0.8} Cs_{0.2}Pb(I_{0.7}Br_{0.2} Cl_{0.1})₃ on ITO/PTAA, 70 μl of DMF will be spin-coated at 6,000 r.p.m. for 10 s. 100 μL of the perovskite precursor solution will be spin-coated at 500 rpm for 2s, then at 4000 rpm for 60 s with 750 μL diethyl ether dripping as anti-solvent at the 25s of the second step. The prepared film will be annealed at 65° C. for 2 min then 100° C. for 10 min. 2 mg Phenethylammonium iodide (PEAI) will be dissolved in 1 ml isopropanol and spin-coated on top of perovskite film at 3000 rpm for 30 s without annealing. 2 mg PCBM/1 ml chlorobenzene will be spin coated on top of the PEAI interface at 700 rpm for 30 s coupled with 5000 rpm for 10 s, followed by annealing at 70° C. for 10 minutes. Rd solution (5 mg Rd will be dissolved in 10 ml Isopropanol) will be spin coated at 4000 rpm for 40 seconds. Finally, 100 nm of Ag will be thermally evaporated at a pressure 10⁻⁷ Pa. Optical, electrical, and morphological properties of all films and PV devices will be fully characterized as described in subtask 1.5.

FIG. 5 and Table 1 show some preliminary results including a) forward and b) reverse scan of the most common MAPbI₃, and wide bandgap (WBG) single junction perovskite solar cells and their photovoltaic parameters. Wide bandgap (1.19 V), and the most common CH₃NH₃PbI₃ (1.05 V) single junction perovskite solar cells have been fabricated and achieved very good preliminary efficiencies of 17.17%, and 18.12%, respectively.

TABLE 1
Showing photovoltaic parameters of MAPbI3, and
WBG single junction perovskite solar cells.

| | |
|---|---|
| WBG Perovskite | CH₃NH₃PbI₃ |

| | Forward | Reverse | Forward | Reverse |
|---|---|---|---|---|
| Jsc (mAcm⁻²) | 18.7 | 18.7 | 23 | 22.9 |
| Voc (V) | 1.19 | 1.17 | 1.02 | 1.05 |
| FF | 0.77 | 0.78 | 0.7 | 0.75 |
| PCE (%) | 17.2 | 17.2 | 16.3 | 18.1 |

### Optimization of Tunnel Recombination Junctions Between the Subcells and a Transparent Top Electrode

### ITO as TRJ between c-Si rear and CH₃NH₃PbI₃ Middle Subcells

To avoid damage to underneath subcells, ITO thin films should be deposited at low temperature less than 100° C. Thermal evaporation is possible, but difficult for ITO. Since indium oxide and tin oxide evaporate at different vapor pressures, it is hard to control their stoichiometry using thermal/e-beam evaporation. For these reasons, sputtering is the preferred method of depositing thin films of ITO. Sputtering can help to improve consistency and repeatability.

### PEIE/AZO/ITO as TRJ between CH₃NH₃PbI₃ Middle and FA_{0.8} Cs_{0.2}Pb(I_{0.7}Br_{0.2} Cl_{0.1})₃ Front Subcells

TRJ should be prepared at low temperatures not to damage the pre-deposited layers and to be protective enough to avoid washing the bottom perovskite while depositing the top one. The reason why 200 nm thick indium tin oxide (ITO) layer will be sputtered to protect the underlying bottom cell from solvent damage. However, direct sputtering of TCO films may cause plasma-induced damage to organic and perovskite absorbers resulting in degradation, so a protective buffer layer is required on top of perovskite and organics before sputtering. Ethoxylated poly-ethylenimine (PEIE) layer forms interfacial dipoles at the ZnO/polymer interface, which lowers the energy barrier, improves electron extraction, minimizes charge trapping at the interface, and protects the underlying perovskite layer during the ITO sputtering. PEIE contains the nucleophilic hydroxyl and amine functional groups that enhance AZO nucleation. This results in AZO layer with higher crystallinity and larger crystal size, superior coverage, lower water vapor transmission rate, and higher stability. AZO layer from a sol-gel precursor can be processed at low temperatures suitable for the perovskite and polymer materials. PEIE layer may be prepared by mixing 0.1 wt % of PEIE with 2-methoxyethanol (ME), spin-coating at 5000 rpm for 20 s, and annealing at 100° C. for 2 min. AZO layer may be sol-gel synthesized by dissolving 2.17 g of zinc acetate dehydrate [Zn(CH₃ COO)₂·2H₂O] and 3.8 mg of aluminum nitrate nonahydrate [Al(NO₃)₃·9H₂O] in 100 ml of ethanol at 80° C. for 2.5 hours followed by filtering using a 0.45 Mm PVDF filter to remove any formed precipitate. The Sol-gel AZO will be spin coated at 3000 rpm for 60 seconds to form a 25 nm thick film. The samples were then annealed at 150° C. for 10 minutes.

### Transparent Electrode

Rhodamine interfacial layer at the PCBM/Ag interface should not be annealed to maintain its properties, while the top Ag metal contact needs to be transparent to allow illumination from the top subcell. Rhodamine and Ag metal contact layers will be replaced with ZnO and Ag nanowire layers, respectively. ZnO layer will be prepared by spin coating ZnO-NP solution onto PCBM layer then annealed at >120° C. to give a 100 nm thick ZnO film. This film will be compared with the ZnO layer prepared by sputtering. Ag nanowire electrodes will be deposited onto the ZnO layer from Ag nanowire suspension (0.5% in Isopropanol) by spin coating. The Ag nanowire film thickness, annealing temperature, and annealing time will be optimized to achieve the maximum performance.

### Characterization of the Prepared Films and Photovoltaic Devices

Absorbance of the subcells absorbing materials will be measured using UV-Vis spectroscopy from which we can estimate their bandgaps. Crystallinity of the prepared perovskite films will be characterized by X-ray diffraction (XRD) to confirm complete conversion of the precursors into highly pure perovskites and for measuring the crystal size. Atomic force microscope (AFM) will be used to check perovskite film roughness and grain size by measuring topography. Kelvin prop force microscope (KPFM) will be used for measuring surface potential of device layers to confirm energy level are well aligned for collection of the generated carriers. JV curves of the prepared devices will be measured under illumination using a solar simulator at 1.5 AM from which we can calculate the PV parameters including short circuit current (Jsc), open circuit voltage (Voc), fill factor (FF), series resistance, and shunt resistance. External quantum efficiency (EQE) of the PV devices will be measured using solar simulator, monochromator, trans-impedance amplifier, and reference photodetector from which we can calculate the current generated at each wavelength and the integrated current density of all wavelengths. Transient will be measured for the PV devices to be sure that charge transport time is shorter than carrier lifetime. This confirms that electron and hole transport layers are highly efficient, thus carriers will be collected to electrodes rather than recombine.

### Intrinsically Integrate the All-Solid State Li Ion Battery with the Triple Junction Solar Cell

The final device structure of solar batteries is shown in FIG. 6. To realize the device, triple junction Si/CH₃NH₃PbI₃/WBG perovskite solar cell were fabricated as discussed above, and then Al evaporated on top of the hole collector of the solar cell (Ag). This Al will act as the cathode current collector of the battery. The battery cathode ink (LFP ink) is then cast on top of the evaporated Al and anneal it overnight at low temp (60° C.) under vacuum. Afterwards, LTO/Cu anode electrode may be prepared with two terminals. Solid polymer/garnet electrolyte membrane will then be prepared. The integrated solar battery device may be assembled by stacking together the solar cell/battery cathode, anode, and electrolyte membrane. One of the Cu terminals is bent and then soldered with the Ag nanowires evaporated on the other side of the triple junction solar cells. The integrated device will be well sealed for characterization. Battery photo-charging by solar cell will be measured using a solar simulator and connecting the battery terminals to the battery tester to record the photo-charging data and get the charging voltage profile. The photo-charged battery will be discharged gelvanostatically by the battery tester, so we can get the discharge voltage profile.

FIG. 6a shows the photo-charging mechanism by a converter. FIG. 6b shows photo-charge and galvanostatic discharge voltage profiles of one of our designed solar batteries for 20 cycles charging/discharging between potential window of 1.0-3.14 V followed by another 10 charging/discharging cycles powered by a standard DC supply. This confirmed that photo-charging of solar batteries was as effective as the conventional DC source charging. FIG. 6c shows the discharge capacities of our newly designed solar batteries between 155.2 mAh/g (1 st cycle) and 115.1 mAh/g (20th cycle) followed by 107.1 mAh/g (21 st cycle) to 99.5 mAh/g (30th cycle) reflecting the high reversibility of the LIB when photo-charging or DC conditions. The rate capability of the PSC/LIB integrated cell is shown in FIG. 6d. Our prior accomplishments in solar batteries demonstrated a discharge capacity of 142.2 mAh/g at C/5 and 71.9 mAh/g at high 4 C rates. After the high rate cycling, the device demonstrated excellent recovery of 128.2 mAh/g, accounting to retention of ˜93% of the initial capacity at 2 C charge/1 C discharge rates.

The present invention provides a new solar battery product that is not only beneficial for decarbonization, but also for energy savings as follow: 1) Clean renewable photovoltaics are an established renewable energy source alternative to legacy fossil fuels, which contributes to high carbon emission, air pollution, and global warming. 2) Hybrid solar batteries can provide solar energy as a back-up power source for use at other times when solar renewables are intermittent, unavailable, unstable, or unreliable. 3) Hybrid solar batteries eliminate the use of an extra electrode, cables, and inverters, thus saving space and weight, while simplifying design, and decreasing the costs of solar panel installation. 4) Hybrid solar batteries using solid-state Li metal or ion batteries improve safety compared to liquid electrolyte batteries which suffer from leakage and other safety issues such as flammability, and even explosion. 5) Performance of our hybrid solar battery products will be improved to accomplish superior capacity (>300 mAh/g) and energy density (up to 500 Wh/Kg). 6) The hybrid solar batteries will be connected in series and parallel to develop a panel to achieve the required voltage and power for the required demand for at nighttime, cloudy, rainy and snow days.

### EXAMPLE

FIG. 7a depicts device architecture of rear illuminated PSC with integrated storage from a Li₄Ti₅O₁₂-LiCoO₂_LIB. A planar triple cation PSC (FIG. 7b) was fabricated on titanium metal substrate with a semi-transparent top electrode (dielectric-metal-dielectric (DMD): MoO₃-Au/Ag-MoO₃). Meanwhile, on the other side of titanium substrate, Li₄Ti₅O₁₂-LiCoO₂ LIB (FIG. 7c) was fused. Li₄Ti₅O₁₂ as anode can facilitate stable and safe battery cycling operation. It can provide a reasonable capacity without undergoing reduction below 1 V, unlike graphite or silicon anodes which undergo reduction close to Li reduction potential, thus leading to unstable solid electrolyte interphase and possible early battery failure. FIG. 7d,e display scanning electron microscope (SEM) cross section images of the PSC and LIB, respectively. The perovskite layer has a thickness of ˜550 nm. The spiro-OMeTAD forms a uniform covering on top of the perovskite layer. The Li₄Ti₅O₁₂ anode forms an efficient contact with the titanium foil and the observed gap is due to non-pressed battery components and imperfect sample cutting for cross-section.

### Photovoltaic Performance of Rear Illuminated PSCs on Titanium Metal Electrode

The use of metal substrate for PSCs requires illumination from the top electrode (rear illumination, FIG. 7) in comparison to front illuminated conventional glass substrate PSCs with an opaque metal top electrode. This requires the adoption of a transparent top electrode instead of the conventional opaque metal electrode. In this work, a semi-transparent DMD structure serves as such top electrode, whose structure has the capability of increasing the light-transmission due to interference effects provided by the two dielectric layers. The DMD employed consisted of MoO₃ (10 nm)/Au(1 nm)/Ag(10 nm)/MoO₃(40 nm) as shown in FIG. 10a, in which MoO₃ was mainly used due to its efficient hole transport properties, but it can also provide a good nucleation surface for metal film deposition. A PSC fabricated on top of the titanium metal substrate was covered by such DMD structure.

The perovskite layer is composed of Cs-containing mixed triple cation and iodide/bromide formulation. Front illuminated PSCs fabricated on a fluorine doped tin oxide (FTO) glass substrate and with Ag top electrode demonstrated PCE of 18.74% (FIG. 8a) and average PCE of 18.35% (FIG. 8c, FIG. 1 ) along with some degree of hysteresis. Meanwhile, the J-V characteristic curves of rear illuminated PSC fabricated on titanium metal substrate with the semi-transparent DMD as top electrode are shown in FIG. 8b. The champion rear illuminated cell demonstrated PCE of 10.96% with J_{SC} of 15.45 mAcm⁻², V_{OC} of 1.09 V and fill factor of 0.656. Major reason for the observed reduced efficiency of the metal-based PSC is rear illumination, where the amount of light received by the perovskite decreases as the DMD electrode is not as transparent to the conventional FTO electrode and in addition, part of ultraviolet-visible light is absorbed by spiro-OMeTAD (FIG. 13). FIG. 11b shows the external quantum efficiency (EQE) spectrum of the PSC with integrated J_{SC} of 15.37 mAcm⁻², which is in good agreement with the J_{SC} extracted from the J-V measurements. The cell demonstrated stabilized power output at PCE of 10.65% as shown in FIG. 11c. FIG. 8d shows the statistical distribution of photovoltaic performance parameters of rear illuminated 25 devices. The average rear illuminated PCE obtained is 10.25%, which is lower than front illuminated FTO-based PSCs. Furthermore, the performance of metal-based PSCs (FIG. 8, FIG. 11) are comparable to the semi-transparent PSCs fabricated on FTO substrates with DMD as top electrode (FIGS. 15, 16).

A trade-off exists between transparency and conductivity. One is usually achieved at the expense of the other. The thin 10 nm Ag electrode is highly resistive, which can be attributed to the tendency of the atoms to bind to each other rather than to the substrate. This leads to a Volmer-Weber (island) growth forming a non-continuous Ag film as shown by atomic force microscopy (AFM) topography image (FIG. 17c). The Ag film has a rough surface with arms value of 10.01 nm (FIG. 8e). Use of 1 nm thick Au film as a seed layer for Ag deposition leads to a very compact Ag film (FIG. 17d). The Ag film's roughness decreased to 1.4 nm (FIG. 8f) attributed to the Frank-van der Merwe (layer-by-layer) growth of Ag, enabled by the Au seed layer underneath. A conductive Ag film was obtained as evidenced by the current sensing (CS)-AFM image (FIG. 17b), where the film exhibits high surface current that is uniform all over the surface.

Optical images of the Au, Ag, Au/Ag, MoO₃/Au/Ag, MoO₃/Au/Ag/MoO₃ electrodes are shown in FIG. 18. FIG. 8g shows the transmittance of the semi-transparent top electrode with different layers and thickness as function of wavelengths. The 10 nm thick Ag electrode is only 40% transparent at 550 nm, while the Au seed layer increased the transmittance to 55%. Meanwhile, DMD showed a transmittance of 80% at 550 nm with decreasing transparency towards the infrared region. The increase in transparency in the visible region can be attributed to the optical interference effects created by use of MoO₃ on bottom, metal Au/Ag layer in middle and MoO₃ on top. The top MoO₃ also served as an anti-reflection coating.

### Photo-Electrochemical Charge/Discharge Performance

FIG. 9a schematically illustrates the operating mechanism of the rear illuminated perovskite solar cell with integrated lithium ion battery storage coupled with converter, upon charging and discharging. Upon rear illumination, the photo-generation of electron and holes occurs in the perovskite film. The holes will travel towards the hole transport layer (Spiro-OMeTAD) and the electrons towards the electron transport layer (SnO₂/PCBM). The current flows into a voltage boost converter and steps up the produced voltage from the PSC to a threshold value that matches the electrochemical potentials of the anode and cathode couple in LIB, resulting in oxidation of cathode (LiCoO₂) that induces the release of Li⁺ into electrolyte followed by migration towards anode (Li₄Ti₅O₁₂). Meanwhile, the electron injection into anode lattice results in Li₄Ti₅O₁₂ reduction and corresponding Li⁺-intercalation into the anode framework. While part of the energy generated by PSC is consumed during the voltage step-up process, most is stored as chemical energy in the charged LIB. The stored energy can be released by discharging LIB to supply a load where Li⁺ flows from anode to cathode via electrolyte and electrons through the load.

FIG. 9b shows photo-charge and galvanostatic discharge voltage profiles of the rear illuminated perovskite solar cell with intrinsically integrated storage for 20 cycles between potential window of 1.0-3.14 V followed by another 10 charge/discharge cycles powered by a standard DC supply. Almost identical charge/discharge voltage profiles were displayed by the integrated PSC photo-charging and DC supply charging, indicating that the photo-charging of the integrated cell was as effective as the conventional DC source. It should be noted that the charging voltage had a plateau at ˜2.5 V at 2 C while the discharge plateau was observed at ˜2.25 V at 1 C, indicating low over-potential loss. FIG. 9c shows the galvanostatic discharge capacities of the integrated cell with PSC photo-charging and DC charging. Capacities between 155.2 mAh/g (1^{st} cycle) and 115.1 mAh/g (20^{th} cycle) were delivered from PSC photo-charging followed by 107.1 mAh/g (21^{st} cycle) to 99.5 mAh/g (30^{th} cycle) from DC supply charging. The closeness of these two sets of data reflected the identical operation of LIB and the high reversibility of its electrochemistries under both photo-charging or DC conditions. The rate capability of the PSC/LIB integrated cell is shown in FIG. 9d. The integrated cell demonstrated discharge capacity of 142.2 mAh/g at C/5 and 71.9 mAh/g at high 4 C rates. After the high rate cycling, the device demonstrated excellent recovery of 128.2 mAh/g, accounting to retention of ˜93% of the initial capacity at 2 C charge/1 C discharge rates

### Efficiency and Maximum Power Point Performance

The performance of the rear illuminated perovskite solar cell with intrinsically integrated storage was evaluated by overall photoelectric conversion-storage efficiency (ηₒᵥₑᵣₐₗₗ) and energy storage efficiency (η_{storage}). The ηₒᵥₑᵣₐₗₗ measures the output (discharge) energy of the battery for a given input light energy and is defined as:

$${η}_{overall} = {E}_{discharge} / ( {P}_{in} \times A \times {t}_{ch} ) \times 100 \% \qquad ( 1 )$$

while the energy storage efficiency (η_{storage}) measures the output (discharge) energy of the battery to the input (charge) energy. For photo-charging, η_{storage} is defined as:

$${η}_{storage ( photo )} = {η}_{1} / {η}_{PV} \times {η}_{coverter} \times 100 \% \qquad ( 2 )$$

$$For dc ch arging , {η}_{storage} is defined as :$$

$${η}_{storage ( dc )} = {E}_{discharge} / {E}_{charge} \times 100 \% \qquad ( 3 )$$

where, E_{discharge} and E_{charge} are the discharge and charge energies (mWh) of battery, Pᵢₙ is the input light intensity (100 mWcm⁻²), A is the PV area (cm²) and t_{ch} is the photo-charging time (h), η_{PV} is the photo-electric conversion efficiency and η_{converter} is the converter efficiency.

The ηₒᵥₑᵣₐₗₗ of the rear illuminated perovskite solar cell with intrinsically integrated storage was calculated using equation (1) and is shown in FIG. 10a. The integrated cell had a ηₒᵥₑᵣₐₗₗ as high as 7.3% with an average of 6.78%, while the converter efficiency (η_{converter}) was averaged at 88% (FIG. 20). Thus obtained ηₒᵥₑᵣₐₗₗ outperforms previous efforts on stackable integrated designs based on organic-inorganic photovoltaics. However, this ηₒᵥₑᵣₐₗₗ of this integrated design is lower than that achieved with the discrete design at 9.36%. This can be attributed to the lower solar cell efficiency owing to its different solar cell architecture requiring light illumination from the rear electrode.

FIG. 10b shows the energy storage efficiency of the PSC/LIB integrated cell for photo-charging, calculated using equation (2) and DC charging using equation (3). The average storage efficiency was 78.9%, which is close to the 80.6% efficiency of DC charging the integrated cell. The average value of coulombic efficiency of the integrated cell under DC charging was 98.46%. Kapton tape and epoxy were used to encapsulate the integrated devices. No additional encapsulation was applied on the integrated cells during the characterization and testing. For long term cycling studies, hermetically sealed encapsulation of both the PSC and LIB will be employed. Recent research in perovskite photovoltaics is geared toward addressing the technology's problem of long-term stability in response to moisture, heat, continuous illumination and air; therefore, we expect several breakthroughs in achieving better stability in regard to the material's intrinsic chemical stability and device encapsulation. Sensitivity studies have shown that the perovskite PV modules possess the shortest energy payback time compared to other solar cell technologies such as Si, CdTe and organic PVs. The modules are potentially the most environmentally sustainable technology considering their satisfactory long-term performance. Furthermore, solid-state batteries can be employed to address the long-term and thermal stability of the integrated cell. The energy conversion technology and design implemented in this work is promising for energy sustainability.

The voltage boost converter facilitates the photo-charging with maximum power point tracking (MPPT) of the produced PV power. The MPPT is based on the fractional open circuit voltage technique and is designed to operate at 78% of the open circuit voltage of the input power source. The converter samples the open circuit voltage of the solar cell every 16 s. For this, the boost converter is disabled so the solar cell can return to its open circuit voltage. The sampling period of the converter is 256 ms. This is enough time for the output current to charge the internal solar cell capacitance and for board capacitance to settle the voltage to the open circuit voltage, even in low light conditions. The converter sets a charging cut-off voltage at 3.14 V, which is suitable for the Li₄Ti₅O₁₂-LiCoO₂ battery to fully charge. For the converter to start up, a minimum voltage of 300 mV and power of 0.01 mW are required, which can be definitely provided by the PSC in this work. The voltage at the maximum power point (V_{MPP}) was measured from the J-V characteristics of the PSC/Li₄Ti₅O₁₂-LiCoO₂ integrated cell for 20 charge/discharge cycles. FIG. 10c shows the operating voltage during charging when MPPT was active and inactive and was compared to the V_{MPP}. V_{MPP} ranged from^{-0.814} V for 1 st cycle to 0.756 V for 20^{th} cycle. As seen, during the active MPPT mode, the voltage at which the PSC operated during battery charging was close to the V_{MPP} compared to the inactive MPPT voltage. Coupling factor is a parameter that defines how close to the PV maximum power point the battery charging occurs. Coupling factor is the ratio of the actual PV input power used for battery charging to the maximum PV power.

$$Coupling factor = PV input power / maximum PV power \qquad ( 4 )$$

FIG. 10d shows that the coupling factor averaged 0.912 for active MPPT. This indicated that during the MPPT period, the PV output power was 91.2% of the actual maximum power. The inactive MPPT period had a coupling factor that averaged 0.739. These observations reveal that the MPPT implementation was critical to achieve the optimum performance of the integrated cell. FIG. 10e shows the variation of ηₒᵥₑᵣₐₗₗ with C-rate for photo-charging, where the integrated cell was able to retain an ηₒᵥₑᵣₐₗₗ of 6.77% at 2 C charge/1 C discharge rates after the device was stressed to high rates at 4 C. Further, as shown in FIG. 10f, the average efficiency of perovskite solar cell showed a steady decline in PCE from^{-10.07}% to 9.26% with cycling.

In summary, converter-assisted photo-charging of a monolithically integrated power pack that consists of a single junction perovskite solar cell as power generation with a lithium ion battery for energy storage was demonstrated. This design enables rigid mechanical isolation which simplifies the monolithic stacking of the solar cell and battery, while providing electrical interconnection. This integrated power pack delivers high overall photoelectric conversion-storage efficiency of 7.3% under photo-charging, outperforming other efforts on stackable integrated designs based on organic-inorganic photovoltaics. This superior performance was attributed to the MPPT of the PV generated power, efficient perovskite solar cell, low over-potential loss in Li₄Ti₅O₁₂-LiCoO₂ Li-ion chemistry and in situ charge transfer via the common metal electrode. While this photo-rechargeable integrated power pack can serve as candidate power supply for sensors, portable electronics and wearables, the integration strategy established in the work represents a design advancement in miniaturizing the footprint of power-conversion and energy-storage technologies.

Materials. Formamidinium iodie (FAI), methylammonium bromide (MABr), tris(2-(1H-pyrazol-1-yl)-4-tert-butylpyridine)-cobalt(III) tris(bis (trifluoromethylsulphonyl)imide) (FK209) were purchased from Dyesol and were used as received. Lead iodide (PbI₂) was purchased from Acros Organics. Lead bromide (PbBr₂), cesium iodide (CsI), bis (trifluoromethane) sulfonimide lithium salt (LiTFSI) and 4-tert-butylpyridine (tBP) were purchased from Sigma-Aldrich. Spiro-OMeTAD was purchased from Luminescence Tech. Phenyl-C61-butyric acid methyl ester (PC₆₁BM) was purchased from Nano-C. Tin (IV) oxide (15% in H₂O colloidal dispersion) was purchased from Alfa Aesar. Liquid reagents such as N,N-dimethylformamide (DMF, 99%), dimethyl sulfoxide (DMSO, 99.7%), chlorobenzene (CB, 99.8%), acetonitrile, ethanol were purchased from Acros Organics and used as received.

Fabrication of semi-transparent perovskite solar cells. First, substrate (FTO/glass, titanium metal) was cleaned in detergent water, de-ionized water, acetone and isopropyl alcohol using ultra-sonication for 20 min each. The cleaned substrates were then UV-ozone plasma treated for 25 min. A thin layer of compact SnO₂ layer using aqueous SnO₂ colloidal precursor solution was spin coated on top of the cleaned substrates at 3000 rpm for 30 s and was annealed at 150° C. for 30 min. After cooling down to 100° C., the substrates were transferred to the nitrogen glovebox to deposit the PC₆₁BM and perovskite films.

PC₆₁BM solution in chlorobenzene (1 mg/ml), stirred overnight at 70° C. was spin coated in a a two-step spin process at 3000 rpm for 30 s and 4000 rpm for 5 s. This was followed by annealing at 80° C. for 10 mins. The perovskite solution was prepared by dissolving 1 M FAI, 1.1 M PbI₂, 0.2 M MABr and 0.2 M of PbBr₂ in DMF: DMSO (4:1 vol./vol.) solvent and addition of 1.5 M CsI dissolved in DMSO in 5:95 volume ratio. First, PbI₂ in DMF: DMSO (4:1 vol./vol.), PbBr₂ in DMF: DMSO (4:1 vol./vol.) and CsI in DMSO was heated at 180° C. for 15 mins, 180° C. for 5 mins and 150° C. for 5 mins respectively. After cooling down to room temperature, the FAI and MABr were dissolved in PbI₂ and PbBr₂ solution respectively. Finally, these two mixture solutions were mixed, followed by addition of CsI/DMSO solution. The solution was filtered before use. Perovskite film was spin coated on top of the SnO₂/PC₆₁BM layer in a two-step spin process at 1000 rpm for 10 s and 6000 rpm for 30 s. During the second step, a 200 μL of chlorobenzene was dropped on the spinning substrate 5 s before the end of the second step. The samples were then annealed at 100° C. for 45 min and cooled down.

Spiro-OMeTAD solution was prepared by mixing 70 mM spiro-OMeTAD in chlorobenzene and doped with Li-TFSI acetonitrile solution, 4-tert-butylpyridine and tris(2-(1H-pyrazol-1-yl)-4-tert-butylpyridine)-cobalt (III) tris(bis(trifluoromethylsulphonyl) imide) (FK209) cobalt salt in acetonitrile in a molar ratio of 0.5, 3.3 and 0.03 respectively. Spiro-OMeTAD layer was spin coated at 4000 rpm for 30 s. This was followed by thermal evaporation of 10 nm of MoO₃ layer, DC sputtering of 1 nm Au layer, thermal evaporation of 10 nm of Ag layer and finally 40 nm of MoO₃ layer. For comparison, conventional PSCs with opaque top electrode was also fabricated with a thermally evaporated 100 nm thick Ag top electrode.

Fabrication of Li-ion cell. First, a slurry consisting of Li₄Ti₅O₁₂ (active material), super P carbon black (conductive additive) and polyvinylidene fluoride mixed in 80:10:10 weight ratio respectively in N-Methyl-2-pyrrolidone solvent was prepared. The prepared slurry was then coated on to a copper foil and dried overnight in vacuum oven at 100° C. Circular disks were cut with loading mass of the active material 2.3 mg·cm⁻². CR-2032 full cells with Li₄Ti₅O₁₂ as anode and lithium cobalt oxide (LiCoO₂) as cathode were assembled inside an argon filled glovebox along with 25 μm trilayer polypropylene- polyethylene-polypropylene membrane as separator and 1M LiPF₆ in a mixture of ethylene carbonate: dimethyl carbonate: diethyl carbonate (EC:DMC:DEC) (1:1:1 by volume) solvents as electrolyte.

Fabrication of integrated PSC-LIB cell. The PSC on titanium substrate was fabricated following the above-mentioned procedure. The slurry of Li₄Ti₅O₁₂ was coated on the other side of the titanium substrate and heated at 50° C. for 30 mins. A lower temperature was selected considering the heat-sensitivity of perovskite and spiro-OMeTAD layers. The samples were transferred into an argon-filled glove box. A 25 μm trilayer polypropylene-polyethylene-polypropylene membrane as separator was placed on top of the Li₄Ti₅O₁₂anode. Cathode LiCoO₂/Al was placed on top of the separator. The cell was sealed on three sides with kapton tape. Suitable amount of electrolyte [1 M LiPF₆ dissolved in EC:DMC:DEC (1:1:1 by volume ratio)] was injected from the remaining one side and was sealed using kapton tape and epoxy. No additional encapsulation was applied on the integrated cells during the characterization and testing. For long term cycling studies, hermetically sealed encapsulation of both the PSC and LIB will be employed.

Solar cell characterization. The current density-voltage (J-V) characterization of PSCs was performed under light illumination of 100 mWcm⁻² using Xenon arc lamp (Newport, Model 67005) applying external potential bias using a Keithley 2400 digital source meter. Calibration of the light intensity was done using a NREL-calibrated silicon photodetector. The J-V scans were performed along the forward scan direction from⁻⁰ to 1.2 V and the reverse scan direction from^{-1.2} V to 0 V, at a scan speed of 200 mVs⁻¹ and step voltage of 10 mV. The steady-state efficiencies were obtained by tracking the maximum power point. The active area of the solar cell was 0.16 cm² (0.8 cm×0.2 cm²) and was defined by a mask. External quantum efficiency (EQE) measurements were performed in air using a monochromator coupled with a lock-in amplifier. The cells were illuminated using the same Xenon arc lamp. NREL-calibrated silicon photodetector was used as the reference. No preconditioning protocol was applied before the characterizations.

Battery characterization. Galvanostatic electrochemical performance of the assembled batteries were studied using LAND CT2001A system in a potential range of 1.0 V-3.14 V at different C-rates.

Integrated solar cell/battery characterization. The output of the PSC part of the integrated cell was connected to the input of the DC-DC boost converter bq25504EVM (Texas Instruments) and the cathode of the LIB part of the integrated cell was connected to the output of the converter. The converter has charge cut off voltage of 3.14 V and its characteristics are provided in Table 2.

| Parameter | | Min | Nom | Max | Unit |
|---|---|---|---|---|---|
| V_{IN} (DC) | DC input voltage | 0.13 | | 3.0 | V |
| V_{IN}_{_{—}}_{Start-up} (DC) | DC minimum | | 330 | | mV |
| | start-up voltage | | | | |
| Vₒᵥ | Over voltage | 2.9 | 3.1 | 3.3 | V |
| MPPT | Maximum power | | 78 | | % |
| | point tracking, | | | | |
| | Programmed % of | | | | |
| | open circuit voltage | | | | |
| P_{IN} | Input power range | 0.01 | | 300 | mW |
| | for normal charging | | | | |
| P_{IN}_{_{—}}_{Start up} | Minimum cold-start to | | 10 | 50 | μW |
| | input power start normal | | | | |

The solar PV input voltage, input current, battery voltage and output current were measured using HP24410A multimeter, amprobe 34XR-A multimeter, LAND CT2001A battery analyzer and Mastech MS8268 multimeter respectively. The photo-charging was followed by discharging at a constant current at 1 C with a cut off voltage of 1.0 V using the LAND CT2001A system. After 20 cycles of photo-charging, DC charging/discharging of the integrated cell was performed using the LAND CT2001A system in a potential range of 1.0 V-3.14 V at 2 C charge and 1 C discharge rates.

Ultraviolet-visible (UV-Vis) absorption spectra. The samples for UV-Vis characterization were made on glass by depositing films of Au, Ag, Au/Ag, MoO₃/Au/Ag and MoO₃/Au/Ag/MoO₃. Agilent 8453 UV-Vis spectrophotometer was used to characterize the transmittance of the prepared films. Glass was used as reference.

Scanning electron microscopy (SEM). The surface morphology of the perovskite films and cross-section of the perovskite solar cell and Li-ion cell were studied by Hitachi S 4700N SEM and FEI Quanta 200F SEM/ESEM. The perovskite films were prepared using the same fabrication steps as in the device.

Atomic force microscopy (AFM). Ag (10 nm) and Au(1 nm)/Ag(10 nm) films were prepared to study topography. Atomic force microscopy (AFM) topography characterization was carried out in tapping mode using Agilent 5500SPM equipped with MAC III controller (three lock-in amplifiers) and Multi75E-G budget sensor with Cr/Pt-coated silicon tip with a resonance frequency of ˜75 kHz. CS-AFM measurement of Au/Ag film was carried out in contact mode with a Cr/Ir coated Si tip using budget sensors ContE-G with force constant of 0.2 N/m; radius ˜20 nm; resonance frequency ˜13 kHz) with 1 V sample bias.

### Example 2

Referring to FIGS. 22-31, the present invention further comprises several different approaches for device integration and designs of the devices and panels. First, a Li-metal battery is fabricated based on solid polymer electrolyte and improve its specific capacity via enhancing the ionic conductivity and stability of the solid electrolyte and electrodes.

Next, a battery module comprising many cells is fabricated and connected in parallel with the same structure of the optimized battery cell to increase the areal capacity (based on pouch cell area). Multijunction solar cells are then developed with high voltage made of absorbing materials with different bandgaps via optimization of a tunnel recombination junction. Next, solar batteries with built-in multijunction solar cells are developed from the above step without external cable connection, as seen in FIGS. 22 and 23. The solar battery may then be scaled up to a larger device as seen in FIGS. 24 and 25 for commercialization. A module of 10 integrated devices may be connected in series (as seen in FIG. 26 stacked with FIG. 27 to obtain the module in FIG. 28), then assembly a panel of solar battery pack by connecting five modules in parallel to reach 24V and 1050 Wh based on the materials selected. Finally, the voltage and energy density of solar battery panel may be increased up to 40V and 2000 Wh/m² by improving the overall efficiency of the solar battery, increasing the capacity of the battery, and selecting materials with higher redox potential and larger specific capacity.

What is claimed is:

1. A solar battery, comprising:
a solar cell including at least a first junction formed from perovskite and a second junction formed from perovskite, wherein the first junction and the second junction are connected monolithically in series so that current will flow in a single direction to provide a voltage output; and
a solid state lithium battery coupled to the voltage output of the solar cell.

2. The solar battery of claim 1, further comprising a third junction connected monolithically in series with the first junction and the second junction so that current will flow in the single direction to provide the voltage output, wherein the third junction is formed from crystalline silicon or perovskite.

3. The solar battery of claim 2, wherein the first junction is a wide bandgap subcell formed from FA_{0.8}MA0.1 Cs_{0.1}Pb(I_{0.7}Br_{0.2} Cl_{0.1})₃ perovskite.

4. The solar battery of claim 3, wherein the second junction is a medium bandgap subcell positioned between the first junction and the third junction, and wherein the second junction is formed from CH₃NH₃PbI₃ perovskite.

5. The solar battery of claim 4, wherein the first junction and the second junction are interconnected by a layer of sputtered transparent indium tin oxide.

6. The solar battery of claim 5, wherein the second junction and the third junction are interconnected by a layer of n-doped hydrogenated amorphous silicon.

4. The solar battery of claim 6, wherein the second junction and the third junction are interconnected by a layer of hydrogenated intrinsic amorphous silicon.

8. The solar battery of claim 1, wherein the first junction and the second junction are interconnected by a layer of ethoxylated poly-ethylenimine, aluminum-doped zinc oxide, and indium tin oxide.

9. The solar battery of claim 8, wherein the first junction and the second junction are interconnected by a layer of [6,6]-phenyl C60 butyric acid methyl ester positioned between the layer of ethoxylated poly-ethylenimine, aluminum-doped zinc oxide, and indium tin oxide and the middle subcell.

10. The solar battery of claim 1, further comprising a layer of transparent rhodamine interconnected to the first junction.

11. The solar battery of claim 10, further comprising a layer of [6,6]-phenyl C60 butyric acid methyl ester between the first junction and the layer of transparent rhodamine.

12. The solar battery of claim 11, further comprising a layer of silver positioned on the layer of transparent rhodamine to form a top electrode.

13. The solar battery of claim 1, wherein the solid state lithium battery is formed from a lithium iron phosphate cathode, a solid polymer and garnet electrolyte, and a lithium titanate anode.

14. The solar battery of claim 1, wherein the solid state lithium battery is formed from a lithium cobalt oxide cathode, a solid polymer and garnet electrolyte, and a lithium titanate anode.

15. The solar battery of claim 1, wherein the solar cell and the solid state lithium battery share an electrode positioned between the solar cell and the solid state lithium battery.
